(19) United States
(12) Patent Application Publication
(10) Pub. No.: US 2023/0195783 A1
(43) Pub. Date: Jun. 22, 2023

(54) Speech Enhancement Based on Metadata Associated with Audio Content

(71) Applicant: Sonos, Inc., Santa Barbara, CA (US)

(72) Inventor: Nicholas A.J. Millington, Santa Barbara, CA (US)

(21) Appl. No.: 18/068,494

(22) Filed: Dec. 19, 2022

Related U.S. Application Data
(60) Provisional application No. 63/291,782, filed on Dec. 20, 2021.

(51) Int. Cl. G06F 16/683; G10L 21/02

(52) U.S. Cl. CPC G06F 16/685; G10L 21/02

(57) ABSTRACT

Systems and methods disclosed herein include computing devices and/or computing systems configured to (i) determine portions of audio content comprising speech dialog based at least in part on metadata associated with the audio content, (ii) for individual portions of the audio content containing speech dialog, identify dialog enhancement parameters for application the portions of audio content containing speech dialog, and (iii) playing (or causing to be played) the audio content, where playing the audio content includes applying the dialog enhancement parameters to the portions of audio content containing speech dialog.

### RELATED APPLICATIONS

This application claims the benefit of priority under 35 U.S.C. § 119(e) of U.S. Provisional Application No. 63/291,782, filed Dec. 20, 2021, the content of which is incorporated herein by reference in its entirety.

### FIELD OF THE DISCLOSURE

The present disclosure is related to consumer goods and, more particularly, to methods, systems, products, features, services, and other elements directed to media playback or some aspect thereof.

### BACKGROUND

Options for accessing and listening to digital audio in an out-loud setting were limited until in 2002, when SONOS, Inc. began development of a new type of playback system. Sonos then filed one of its first patent applications in 2003, entitled “Method for Synchronizing Audio Playback between Multiple Networked Devices,” and began offering its first media playback systems for sale in 2005. The Sonos Wireless Home Sound System enables people to experience music from many sources via one or more networked playback devices. Through a software control application installed on a controller (e.g., smartphone, tablet, computer, voice input device), one can play what she wants in any room having a networked playback device. Media content (e.g., songs, podcasts, video sound) can be streamed to playback devices such that each room with a playback device can play back corresponding different media content. In addition, rooms can be grouped together for synchronous playback of the same media content, and/or the same media content can be heard in all rooms synchronously.

### BRIEF DESCRIPTION OF THE DRAWINGS

Features, aspects, and advantages of the presently disclosed technology may be better understood with regard to the following description, appended claims, and accompanying drawings, as listed below. A person skilled in the relevant art will understand that the features shown in the drawings are for purposes of illustrations, and variations, including different and/or additional features and arrangements thereof, are possible.

FIG. 1A shows a partial cutaway view of an environment having a media playback system configured in accordance with aspects of the disclosed technology.

FIG. 1B shows a schematic diagram of the media playback system of FIG. 1A and one or more networks.

FIG. 1C shows a block diagram of a playback device.

FIG. 1D shows a block diagram of a playback device.

FIG. 1E shows a block diagram of a network microphone device.

FIG. 1F shows a block diagram of a network microphone device.

FIG. 1G shows a block diagram of a playback device.

FIG. 1H shows a partially schematic diagram of a control device.

FIGS. 1-I through 1L show schematic diagrams of corresponding media playback system zones.

FIG. 1M shows a schematic diagram of media playback system areas.

FIG. 2A shows a front isometric view of a playback device configured in accordance with aspects of the disclosed technology.

FIG. 2B shows a front isometric view of the playback device of FIG. 3A without a grille.

FIG. 2C shows an exploded view of the playback device of FIG. 2A.

FIG. 3A shows a front view of a network microphone device configured in accordance with aspects of the disclosed technology.

FIG. 3B shows a side isometric view of the network microphone device of FIG. 3A.

FIG. 3C shows an exploded view of the network microphone device of FIGS. 3A and 3B.

FIG. 3D shows an enlarged view of a portion of FIG. 3B.

FIG. 3E shows a block diagram of the network microphone device of FIGS. 3A-3D

FIG. 3F shows a schematic diagram of an example voice input.

FIGS. 4A-4D show schematic diagrams of a control device in various stages of operation in accordance with aspects of the disclosed technology.

FIG. 5 shows front view of a control device.

FIG. 6 shows a message flow diagram of a media playback system.

FIG. 7 shows an example system configured to perform speech enhancement based on metadata associated with audio content according to some embodiments.

FIG. 8 shows an example method performed by a computing device configured to perform speech enhancement based on metadata associated with audio content according to some embodiments.

FIG. 9 shows an example method performed by a computing system configured to perform speech enhancement based on metadata associated with audio content according to some embodiments.

The drawings are for the purpose of illustrating example embodiments, but those of ordinary skill in the art will understand that the technology disclosed herein is not limited to the arrangements and/or instrumentality shown in the drawings.

### DETAILED DESCRIPTION

### I. Overview

Many listeners report being unable to hear spoken dialog clearly while enjoying video content (e.g., television shows, movies, and other video content) on home theater systems. Listeners complain that increasing the volume on their home theater system to better understand the spoken dialog causes other sounds (e.g., music, explosions, crashes, special effects, and other sounds) in the video content to be too loud. But then reducing the volume to make the other sounds more reasonable often makes the spoken dialog difficult to hear and understand. The problem of understanding dialog also exists with some types of audio-only content such as podcasts, audio blogs, and other audio content that may include other sounds in addition to spoken dialog.

Sonos has developed technologies to enhance spoken dialog in audio content to make spoken dialog in audio content easier for listeners to hear and understand.

For example, U.S. application Ser. No. 13/632,731, titled “Providing a multi-channel and a multi-zone audio environment,” filed on Oct. 1, 2012, issued on Dec. 6, 2016, as U.S. Pat. No. 9,516,440, and assigned to Sonos, Inc., discloses, among other features, playback devices configured to implement a “dialog enhancement” mode of operation. When playing audio in the “dialog enhancement” mode described in some embodiments of U.S. Pat. No. 9,516,440, a playback device boosts the volume of the center channel speaker, rolls off the bass frequencies, lowers the volume of surround sound satellite speakers, and emphasizes the speech spectrum (e.g., 300 to 3400 Hz). Playback devices according to some embodiments disclosed in U.S. Pat. No. 9,516,440 determine whether and when to activate the “dialog enhancement” mode of operation based on e.g., whether the audio content is associated with video, what interface via which the playback device received the audio content (e.g., via an interface connected to a television), what application was used to initiate playback of the audio content, and so on. While operating in the “dialog enhancement” mode, the playback device plays all of the audio content according to the “dialog enhancement” configuration, e.g., rolled off bass frequencies, lowered satellite volumes, and boosted speech spectrum (e.g., 300 to 3400 Hz), thereby helping to make the spoken dialog in the audio content easier for listeners to hear and understand.

In another example, U.S. application Ser. No. 14/174,244, titled “Audio output balancing during synchronized playback,” filed on Feb. 6, 2014, issued on Dec. 29, 2015, as U.S. Pat. No. 9,226,087, and assigned to Sonos, Inc., discloses, among other features, playback devices configured to implement limiters configured to attenuate audio content above a playback volume threshold such that the output of the playback device is capped at a certain volume level, thereby improving the acoustic output quality of the playback device. Playback devices according to some embodiments of U.S. Pat. No. 9,226,087 may implement several different limiters based on, for example, acoustic limits associated with different playback devices configured to play audio content in a playback group and characteristics of the audio content to be played by the playback devices in the playback group. In some instances, implementing limiters as described in U.S. Pat. No. 9,226,087 can improve a listener's ability to hear and understand spoken dialog in audio content by limiting the volume of very loud portions of the audio content that may have otherwise caused the listener to reduce the volume of their playback device(s) and/or caused distortion of the audio content during playback, which would make the spoken dialog in the content more difficult to hear and understand absent application of the disclosed limiter features.

Additionally, U.S. application Ser. No. 14/684,208, titled “Identification of audio content facilitated by playback device,” filed on Apr. 10, 2015, issued on Jun. 13, 2017, as U.S. Pat. No. 9,678,707, and assigned to Sonos, Inc., discloses, among other features, playback devices configured to provide metadata to a control device, where the metadata is related to the audio content that is played by the playback device. Although not directly related to improving the intelligibility of spoken dialog, some aspects of U.S. Pat. No. 9,678,707 are relevant to certain features disclosed and described herein. For example, playback devices according to some embodiments of U.S. Pat. No. 9,678,707 are configured to perform functions comprising (i) receiving data representing audio content, (ii) sending a portion of the data to an identification system configured to identify the audio content based on the portion of the digital data, (iii) receiving metadata associated with the audio content from the identification system, (iv) after receiving the metadata, sending the received metadata to a control device that is configured to control the playback device, and (v) playing the audio content via one or more speakers. While U.S. Pat. No. 9,678,707 describes several useful applications of retrieving metadata associated with the audio content played by playback devices, U.S. Pat. No. 9,678,707 does not describe using the metadata to specifically control or alter playback of the audio content.

Finally, U.S. application Ser. No. 15/670,361, titled “Wake-word detection suppression,” filed on Aug. 7, 2017, issued on Nov. 12, 2019, as U.S. Pat. No. 10,475,449, and assigned Sonos, Inc., discloses, among other features, networked microphone devices configured to detect and disregard wake words appearing in audio content played by playback devices. Although not directly related to improving the intelligibility of spoken dialog, some aspects of U.S. Pat. No. 10,475,449 are relevant to certain features disclosed and described herein. For example, playback devices (including networked microphone devices) according to some embodiments of U.S. Pat. No. 10,475,449 are configured to perform functions comprising (i) storing audio content in memory (e.g., in a buffer) before playing the audio content, (ii) running a wake word detection algorithm on the audio content, and (ii) if any wake words are detected in the audio content, causing one or more networked microphone devices (including perhaps the playback device itself) to disregard the wake words in the audio content so as not to trigger activation of further voice processing for a voice assistance/control service associated with the playback device.

The entire contents of U.S. Pat. Nos. 9,516,440; 9,226,087; 9,678,707; and 10,475,449 are incorporated herein by reference for all purposes. Additionally, the entire contents of U.S. Prov. 63/224,491, titled “Wireless Streaming of Audio/Visual Content in a Home Theater Architecture,” filed on Jul. 22, 2021, and assigned to Sonos, Inc., are also incorporated herein by reference.

In view of the significant advances described above in making spoken dialog (sometimes referred to herein simply as dialog) in audio content easier for listeners to hear and understand, it is desirable to further improve the intelligibility of spoken dialog in audio content in order to enhance the performance of playback devices and further increase listener enjoyment and satisfaction, particularly in the area of home theater. The embodiments disclosed herein continue to expand upon Sonos's history of innovation in audio technology in general, and home theater in particular, by further improving the intelligibility of dialog in audio content. To address long felt needs in the audio playback arts, embodiments herein include playback devices and/or computing systems configured to implement dialog enhancement procedures based at least in part on metadata associated with the audio content. This metadata associated with the audio content is sometimes referred to herein as audio content metadata.

In contrast to current state-of-the-art systems that may apply dialog enhancement techniques regardless of whether audio content actually includes dialog, some of the embodiments disclosed and described herein implement dialog enhancement techniques that actively apply dialog enhancement to specific portions of audio content that include dialog, while not applying the dialog enhancement to other portions of the audio that do not include dialog. This type of active dialog enhancement enables listeners to better hear the dialog within the audio content, while not detracting from listener enjoyment of other parts of the audio content without dialog that may have otherwise been negatively affected by the application of dialog enhancement techniques absent the technical capabilities of the solutions implemented by the embodiments disclosed and described herein.

For example, some embodiments include a computing device (e.g., a playback device) configured to determine at least a portion of audio content comprising dialog (or other speech content) based at least in part on audio content metadata. And for an individual portion of the audio content determined to include dialog (or other speech content), the computing device applies one or more dialog enhancement parameters while playing back the audio content to that individual portion of the audio content determined to include the dialog. In some embodiments, the audio content metadata includes closed caption data associated with the audio content, or perhaps other forms of data that include indications of dialog (or other speech content) that are time-aligned to the audio content.

In some embodiments, a computing system (e.g., a cloud computing system or similar server system) configured to control one or more playback devices is also configured to determine at least a portion of audio content comprising dialog (or other speech content) based at least in part on audio content metadata, where the audio content metadata may include closed caption data or other forms of data that include indications of dialog (or other speech content) time-aligned with the audio content. And for an individual portion of the audio content determined to include dialog (or other speech content), the computing system in some embodiments causes one or more playback devices to apply one or more dialog enhancement parameters to that individual portion of the audio content while playing back the audio content.

In some embodiments, to cause the one or more playback devices to apply the one or more dialog enhancement parameters to individual portions of the audio content comprising dialog while playing back the audio content, the computing system (i) generates a set of dialog enhancement playback control instructions that are time-aligned to the audio content and (ii) sends that set of dialog enhancement playback control instructions to one or more of the playback devices. In operation, the playback control instructions comprise instructions to apply the identified one or more dialog enhancement parameters to the portions of audio content determined to comprise dialog (or other speech content) during playback of the audio content. The set of dialog enhancement playback control instructions may be streamed to the one or more playback devices or sent in the form of a datafile comprising the dialog enhancement playback instructions.

In operation, the one or more dialog enhancement parameters that the playback device(s) apply to the portions of audio content that include dialog are configured to improve the intelligibility of the dialog within the individual portions of the audio content to which the one or more dialog enhancement parameters are applied during playback. For example, in some embodiments, the one or more dialog enhancement parameters include one or more equalization settings, such as amplitudes for one or more frequency ranges that are applied to the portions of the audio content determined to include dialog. In operation, applying the equalization settings to the portions of audio content determined to include dialog in some embodiments includes (i) amplifying content in frequency ranges that tend to include dialog (e.g., between about 300 to 3400 Hz), and/or (ii) attenuating content in frequency ranges that tend to lack dialog (e.g., lower than about 300 Hz and/or above about 3400 Hz).

In some embodiments, the one or more dialog enhancement parameters additionally or alternatively include one or more surround sound settings, such as surround sound delay settings that control the breadth of the sound field, volumes of satellite speakers, surround sound channel mixing settings, and so on. In operation, applying the surround sound settings to the portions of audio content determined to include dialog in some embodiments includes any one or more of (i) increasing the volume of one or more center channel speaker(s), (ii) reducing the volume of one or more satellite speakers, (iii) changing one or more surround sound delay settings to narrow the sound image projected by the center channel speakers, thereby making it easier for a listener focus on the dialog, (iv) changing the directionality of the sound projected by the center channel speakers to focus the sound in narrow region in front of the center channel speaker, and/or (v) mixing some of the center channel information (the channel most likely to contain dialog) into one or more of the satellite channels (e.g., rear left, rear right, overhead, etc.).

While some examples described herein may refer to functions performed by given actors such as “users,” “listeners,” and/or other entities, it should be understood that this is for purposes of explanation only. The claims should not be interpreted to require action by any such example actor unless explicitly required by the language of the claims themselves.

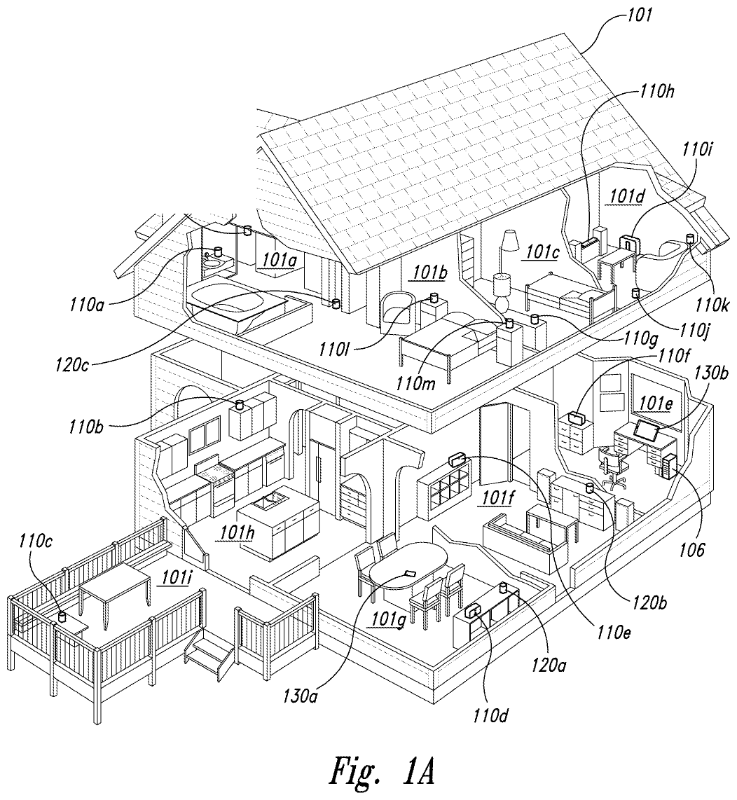

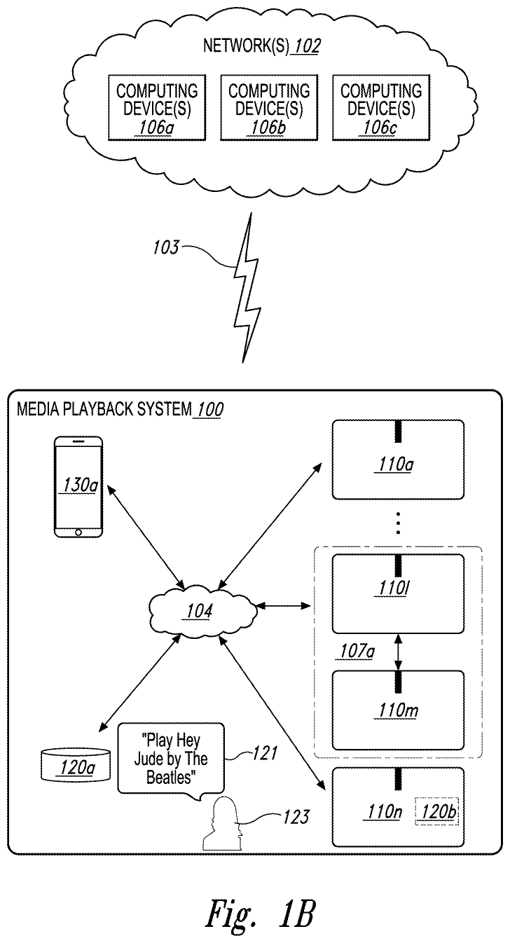

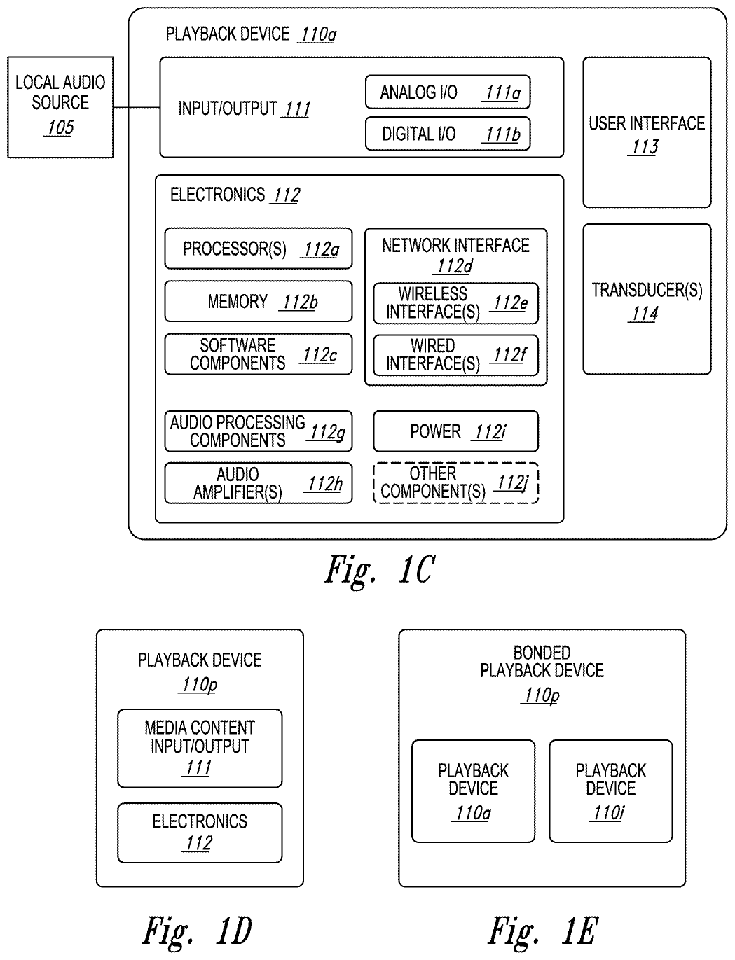

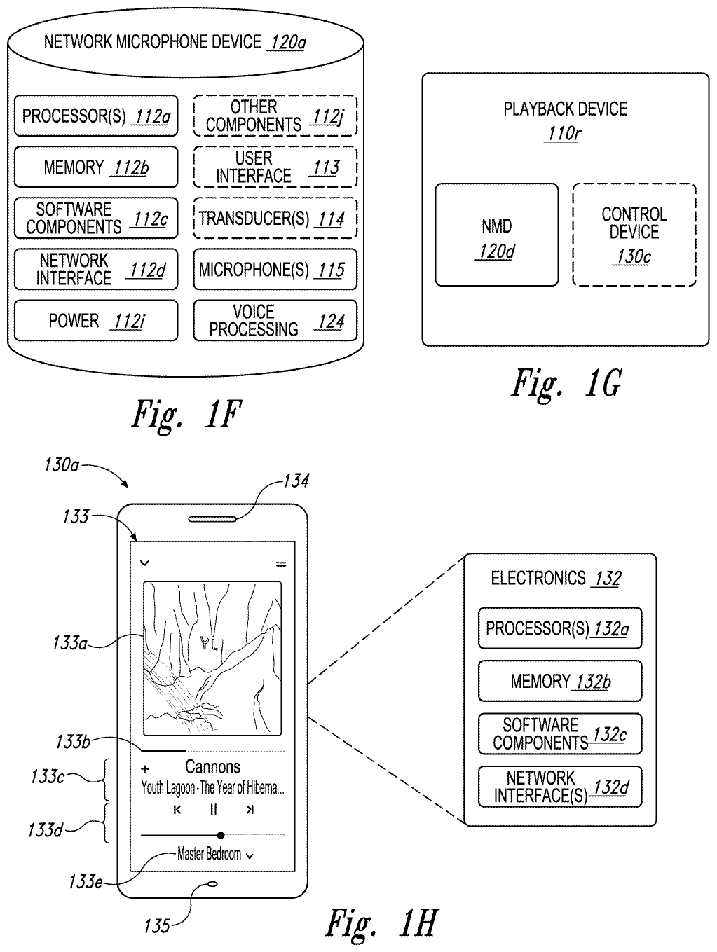

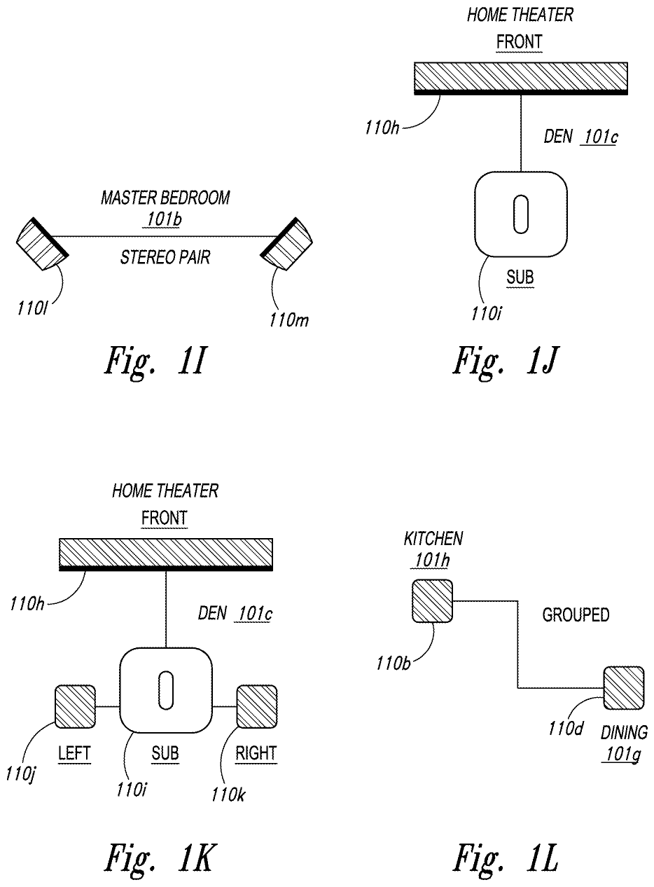

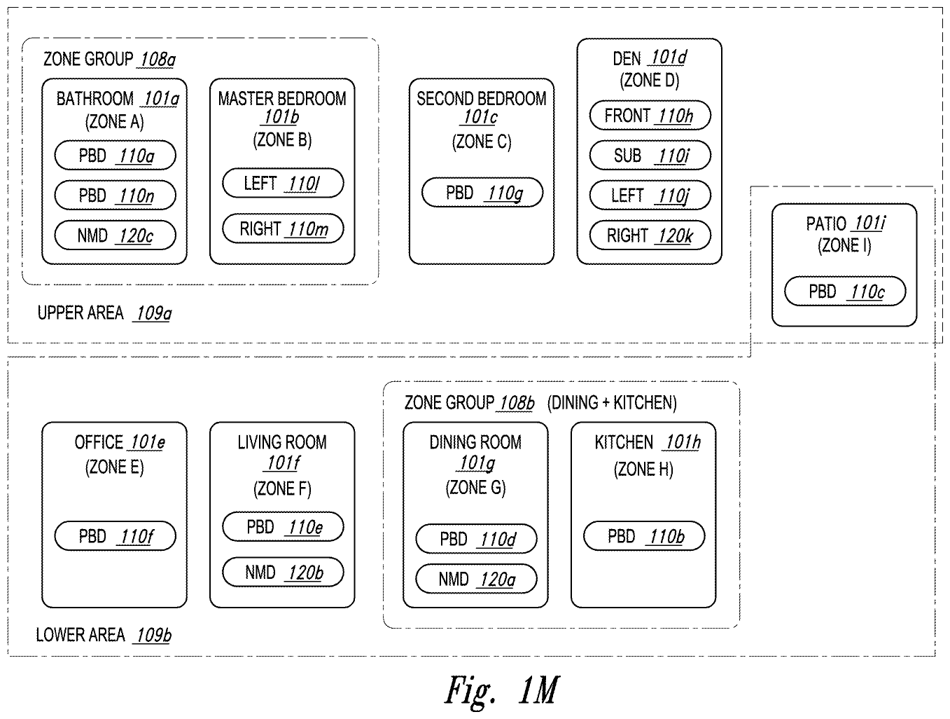

In the Figures, identical reference numbers identify generally similar, and/or identical, elements. To facilitate the discussion of any particular element, the most significant digit or digits of a reference number refers to the Figure in which that element is first introduced. For example, element 110a is first introduced and discussed with reference to FIG. 1A. Many of the details, dimensions, angles and other features shown in the Figures are merely illustrative of particular embodiments of the disclosed technology. Accordingly, other embodiments can have other details, dimensions, angles and features without departing from the spirit or scope of the disclosure. In addition, those of ordinary skill in the art will appreciate that further embodiments of the various disclosed technologies can be practiced without several of the details described below.

### II. Suitable Operating Environment

FIG. 1A is a partial cutaway view of a media playback system 100 distributed in an environment 101 (e.g., a house). The media playback system 100 comprises one or more playback devices 110 (identified individually as playback devices 110a-n), one or more network microphone devices (“NMDs”), 120 (identified individually as NMDs 120a-c), and one or more control devices 130 (identified individually as control devices 130a and 130b).

As used herein the term “playback device” can generally refer to a network device configured to receive, process, and output data of a media playback system. For example, a playback device can be a network device that receives and processes audio data. In some embodiments, a playback device includes one or more transducers or speakers powered by one or more amplifiers. In other embodiments, however, a playback device includes one of (or neither of) the speaker and the amplifier. For instance, a playback device can comprise one or more amplifiers configured to drive one or more speakers external to the playback device via a corresponding wire or cable.

Moreover, as used herein the term NMD (i.e., a “network microphone device”) can generally refer to a network device that is configured for audio detection. In some embodiments, an NMD is a stand-alone device configured primarily for audio detection. In other embodiments, an NMD is incorporated into a playback device (or vice versa).

The term “control device” can generally refer to a network device configured to perform functions relevant to facilitating user access, control, and/or configuration of the media playback system 100.

Each of the playback devices 110 is configured to receive audio signals or data from one or more media sources (e.g., one or more remote servers, one or more local devices) and play back the received audio signals or data as sound. The one or more NMDs 120 are configured to receive spoken word commands, and the one or more control devices 130 are configured to receive user input. In response to the received spoken word commands and/or user input, the media playback system 100 can play back audio via one or more of the playback devices 110. In certain embodiments, the playback devices 110 are configured to commence playback of media content in response to a trigger. For instance, one or more of the playback devices 110 can be configured to play back a morning playlist upon detection of an associated trigger condition (e.g., presence of a user in a kitchen, detection of a coffee machine operation). In some embodiments, for example, the media playback system 100 is configured to play back audio from a first playback device (e.g., the playback device 100a) in synchrony with a second playback device (e.g., the playback device 100b). Interactions between the playback devices 110, NMDs 120, and/or control devices 130 of the media playback system 100 configured in accordance with the various embodiments of the disclosure are described in greater detail below with respect to FIGS. 1B-1L.

In the illustrated embodiment of FIG. 1A, the environment 101 comprises a household having several rooms, spaces, and/or playback zones, including (clockwise from upper left) a master bathroom 101a, a master bedroom 101b, a second bedroom 101c, a family room or den 101d, an office 101e, a living room 101f, a dining room 101g, a kitchen 101h, and an outdoor patio 101i. While certain embodiments and examples are described below in the context of a home environment, the technologies described herein may be implemented in other types of environments. In some embodiments, for example, the media playback system 100 can be implemented in one or more commercial settings (e.g., a restaurant, mall, airport, hotel, a retail or other store), one or more vehicles (e.g., a sports utility vehicle, bus, car, a ship, a boat, an airplane), multiple environments (e.g., a combination of home and vehicle environments), and/or another suitable environment where multi-zone audio may be desirable.

The media playback system 100 can comprise one or more playback zones, some of which may correspond to the rooms in the environment 101. The media playback system 100 can be established with one or more playback zones, after which additional zones may be added, or removed to form, for example, the configuration shown in FIG. 1A. Each zone may be given a name according to a different room or space such as the office 101e, master bathroom 101a, master bedroom 101b, the second bedroom 101c, kitchen 101h, dining room 101g, living room 101f, and/or the patio 101i. In some aspects, a single playback zone may include multiple rooms or spaces. In certain aspects, a single room or space may include multiple playback zones.

In the illustrated embodiment of FIG. 1A, the master bathroom 101a, the second bedroom 101c, the office 101e, the living room 101f, the dining room 101g, the kitchen 101h, and the outdoor patio 101i each include one playback device 110, and the master bedroom 101b and the den 101d include a plurality of playback devices 110. In the master bedroom 101b, the playback devices 110l and 110m may be configured, for example, to play back audio data in synchrony as individual ones of playback devices 110, as a bonded playback zone, as a consolidated playback device, and/or any combination thereof. Similarly, in the den 101d, the playback devices 110h-j can be configured, for instance, to play back audio data in synchrony as individual ones of playback devices 110, as one or more bonded playback devices, and/or as one or more consolidated playback devices. Additional details regarding bonded and consolidated playback devices are described below with respect to, for example, FIGS. 1B and 1E and 1I-1M.

In some aspects, one or more of the playback zones in the environment 101 may each be playing different audio data. For instance, a user may be grilling on the patio 101i and listening to hip hop music being played by the playback device 110c while another user is preparing food in the kitchen 101h and listening to classical music played by the playback device 110b. In another example, a playback zone may play the same audio data in synchrony with another playback zone. For instance, the user may be in the office 101e listening to the playback device 110f playing back the same hip hop music being played back by playback device 110c on the patio 101i. In some aspects, the playback devices 110c and 110f play back the hip hop music in synchrony such that the user perceives that the audio data is being played seamlessly (or at least substantially seamlessly) while moving between different playback zones. Additional details regarding audio playback synchronization among playback devices and/or zones can be found, for example, in U.S. Pat. No. 8,234,395 entitled, “System and method for synchronizing operations among a plurality of independently clocked digital data processing devices,” which is incorporated herein by reference in its entirety.

a. Suitable Media Playback System

FIG. 1B is a schematic diagram of the media playback system 100 and a cloud network 102. For ease of illustration, certain devices of the media playback system 100 and the cloud network 102 are omitted from FIG. 1B. One or more communication links 103 (referred to hereinafter as “the links 103”) communicatively couple the media playback system 100 and the cloud network 102.

The links 103 can comprise, for example, one or more wired networks, one or more wireless networks, one or more wide area networks (WAN), one or more local area networks (LAN), one or more personal area networks (PAN), one or more telecommunication networks (e.g., one or more Global System for Mobiles (GSM) networks, Code Division Multiple Access (CDMA) networks, Long-Term Evolution (LTE) networks, 5G communication network networks, and/or other suitable data transmission protocol networks), etc. The cloud network 102 is configured to deliver media content (e.g., audio data, video data, photographs, social media content) to the media playback system 100 in response to a request transmitted from the media playback system 100 via the links 103. In some embodiments, the cloud network 102 is further configured to receive data (e.g. voice input data) from the media playback system 100 and correspondingly transmit commands and/or media content to the media playback system 100.

The cloud network 102 comprises computing devices 106 (identified separately as a first computing device 106a, a second computing device 106b, and a third computing device 106c). The computing devices 106 can comprise individual computers or servers, such as, for example, a media streaming service server storing audio and/or other media content, a voice service server, a social media server, a media playback system control server, etc. In some embodiments, one or more of the computing devices 106 comprise modules of a single computer or server. In certain embodiments, one or more of the computing devices 106 comprise one or more modules, computers, and/or servers. Moreover, while the cloud network 102 is described above in the context of a single cloud network, in some embodiments the cloud network 102 comprises a plurality of cloud networks comprising communicatively coupled computing devices. Furthermore, while the cloud network 102 is shown in FIG. 1B as having three of the computing devices 106, in some embodiments, the cloud network 102 comprises fewer (or more than) three computing devices 106.

The media playback system 100 is configured to receive media content from the networks 102 via the links 103. The received media content can comprise, for example, a Uniform Resource Identifier (URI) and/or a Uniform Resource Locator (URL). For instance, in some examples, the media playback system 100 can stream, download, or otherwise obtain data from a URI or a URL corresponding to the received media content. A network 104 communicatively couples the links 103 and at least a portion of the devices (e.g., one or more of the playback devices 110, NMDs 120, and/or control devices 130) of the media playback system 100. The network 104 can include, for example, a wireless network (e.g., a WiFi network, a Bluetooth, a Z-Wave network, a ZigBee, and/or other suitable wireless communication protocol network) and/or a wired network (e.g., a network comprising Ethernet, Universal Serial Bus (USB), and/or another suitable wired communication). As those of ordinary skill in the art will appreciate, as used herein, “WiFi” can refer to several different communication protocols including, for example, Institute of Electrical and Electronics Engineers (IEEE) 802.11a, 802.11b, 802.11g, 802.11n, 802.11ac, 802.11ac, 802.11ad, 802.11af, 802.11ah, 802.11ai, 802.11aj, 802.11aq, 802.11ax, 802.11ay, 802.15, etc. transmitted at 2.4 Gigahertz (GHz), 5 GHz, and/or another suitable frequency.

In some embodiments, the network 104 comprises a dedicated communication network that the media playback system 100 uses to transmit messages between individual devices and/or to transmit media content to and from media content sources (e.g., one or more of the computing devices 106). In certain embodiments, the network 104 is configured to be accessible only to devices in the media playback system 100, thereby reducing interference and competition with other household devices. In other embodiments, however, the network 104 comprises an existing household communication network (e.g., a household WiFi network). In some embodiments, the links 103 and the network 104 comprise one or more of the same networks. In some aspects, for example, the links 103 and the network 104 comprise a telecommunication network (e.g., an LTE network, a 5G network). Moreover, in some embodiments, the media playback system 100 is implemented without the network 104, and devices comprising the media playback system 100 can communicate with each other, for example, via one or more direct connections, PANs, telecommunication networks, and/or other suitable communication links.

In some embodiments, audio data sources may be regularly added or removed from the media playback system 100. In some embodiments, for example, the media playback system 100 performs an indexing of media items when one or more media content sources are updated, added to, and/or removed from the media playback system 100. The media playback system 100 can scan identifiable media items in some or all folders and/or directories accessible to the playback devices 110, and generate or update a media content database comprising metadata (e.g., title, artist, album, track length) and other associated information (e.g., URIs, URLs) for each identifiable media item found. In some embodiments, for example, the media content database is stored on one or more of the playback devices 110, network microphone devices 120, and/or control devices 130.

In the illustrated embodiment of FIG. 1B, the playback devices 110l and 110m comprise a group 107a. The playback devices 110l and 110m can be positioned in different rooms in a household and be grouped together in the group 107a on a temporary or permanent basis based on user input received at the control device 130a and/or another control device 130 in the media playback system 100. When arranged in the group 107a, the playback devices 110l and 110m can be configured to play back the same or similar audio data in synchrony from one or more audio content sources. In certain embodiments, for example, the group 107a comprises a bonded zone in which the playback devices 110l and 110m comprise left audio and right audio channels, respectively, of multi-channel audio content, thereby producing or enhancing a stereo effect of the audio content. In some embodiments, the group 107a includes additional playback devices 110. In other embodiments, however, the media playback system 100 omits the group 107a and/or other grouped arrangements of the playback devices 110. Additional details regarding groups and other arrangements of playback devices are described in further detail below with respect to FIGS. 1-I through IM.

The media playback system 100 includes the NMDs 120a and 120d, each comprising one or more microphones configured to receive voice utterances from a user. In the illustrated embodiment of FIG. 1B, the NMD 120a is a standalone device and the NMD 120d is integrated into the playback device 110n. The NMD 120a, for example, is configured to receive voice input 121 from a user 123. In some embodiments, the NMD 120a transmits data associated with the received voice input 121 to a voice assistant service (VAS) configured to (i) process the received voice input data and (ii) transmit a corresponding command to the media playback system 100. In some aspects, for example, the computing device 106c comprises one or more modules and/or servers of a VAS (e.g., a VAS operated by one or more of SONOS®, AMAZON®, GOOGLE® APPLE®, MICROSOFT®). The computing device 106c can receive the voice input data from the NMD 120a via the network 104 and the links 103. In response to receiving the voice input data, the computing device 106c processes the voice input data (i.e., “Play Hey Jude by The Beatles”), and determines that the processed voice input includes a command to play a song (e.g., “Hey Jude”). The computing device 106c accordingly transmits commands to the media playback system 100 to play back “Hey Jude” by the Beatles from a suitable media service (e.g., via one or more of the computing devices 106) on one or more of the playback devices 110.

b. Suitable Playback Devices

FIG. 1C is a block diagram of the playback device 110a comprising an input/output 111. The input/output 111 can include an analog I/O 111a (e.g., one or more wires, cables, and/or other suitable communication links configured to carry analog signals) and/or a digital I/O 111b (e.g., one or more wires, cables, or other suitable communication links configured to carry digital signals). In some embodiments, the analog I/O 111a is an audio line-in input connection comprising, for example, an auto-detecting 3.5 mm audio line-in connection. In some embodiments, the digital I/O 111b comprises a Sony/Philips Digital Interface Format (S/PDIF) communication interface and/or cable and/or a Toshiba Link (TOSLINK) cable. In some embodiments, the digital I/O 111b comprises an High-Definition Multimedia Interface (HDMI) interface and/or cable. In some embodiments, the digital I/O 111b includes one or more wireless communication links comprising, for example, a radio frequency (RF), infrared, WiFi, Bluetooth, or another suitable communication protocol. In certain embodiments, the analog I/O 111a and the digital I/O 111b comprise interfaces (e.g., ports, plugs, jacks) configured to receive connectors of cables transmitting analog and digital signals, respectively, without necessarily including cables.

The playback device 110a, for example, can receive media content (e.g., audio data comprising music and/or other sounds) from a local audio source 105 via the input/output 111 (e.g., a cable, a wire, a PAN, a Bluetooth connection, an ad hoc wired or wireless communication network, and/or another suitable communication link). The local audio source 105 can comprise, for example, a mobile device (e.g., a smartphone, a tablet, a laptop computer) or another suitable audio component (e.g., a television, a desktop computer, an amplifier, a phonograph, a Blu-ray player, a memory storing digital media files). In some aspects, the local audio source 105 includes local music libraries on a smartphone, a computer, a networked-attached storage (NAS), and/or another suitable device configured to store media files. In certain embodiments, one or more of the playback devices 110, NMDs 120, and/or control devices 130 comprise the local audio source 105. In other embodiments, however, the media playback system omits the local audio source 105 altogether. In some embodiments, the playback device 110a does not include an input/output 111 and receives all audio data via the network 104.

The playback device 110a further comprises electronics 112, a user interface 113 (e.g., one or more buttons, knobs, dials, touch-sensitive surfaces, displays, touchscreens), and one or more transducers 114 (referred to hereinafter as “the transducers 114”). The electronics 112 is configured to receive audio from an audio source (e.g., the local audio source 105) via the input/output 111, one or more of the computing devices 106a-c via the network 104 (FIG. 1B)), amplify the received audio, and output the amplified audio for playback via one or more of the transducers 114. In some embodiments, the playback device 110a optionally includes one or more microphones 115 (e.g., a single microphone, a plurality of microphones, a microphone array) (hereinafter referred to as “the microphones 115”). In certain embodiments, for example, the playback device 110a having one or more of the optional microphones 115 can operate as an NMD configured to receive voice input from a user and correspondingly perform one or more operations based on the received voice input.

In the illustrated embodiment of FIG. 1C, the electronics 112 comprise one or more processors 112a (referred to hereinafter as “the processors 112a”), memory 112b, software components 112c, a network interface 112d, one or more audio processing components 112g (referred to hereinafter as “the audio components 112g”), one or more audio amplifiers 112h (referred to hereinafter as “the amplifiers 112h”), and power 112i (e.g., one or more power supplies, power cables, power receptacles, batteries, induction coils, Power-over Ethernet (POE) interfaces, and/or other suitable sources of electric power). In some embodiments, the electronics 112 optionally include one or more other components 112j (e.g., one or more sensors, video displays, touchscreens, battery charging bases).

The processors 112a can comprise clock-driven computing component(s) configured to process data, and the memory 112b can comprise a computer-readable medium (e.g., a tangible, non-transitory computer-readable medium, data storage loaded with one or more of the software components 112c) configured to store instructions for performing various operations and/or functions. The processors 112a are configured to execute the instructions stored on the memory 112b to perform one or more of the operations. The operations can include, for example, causing the playback device 110a to retrieve audio information from an audio source (e.g., one or more of the computing devices 106a-c (FIG. 1B)), and/or another one of the playback devices 110. In some embodiments, the operations further include causing the playback device 110a to send audio information to another one of the playback devices 110a and/or another device (e.g., one of the NMDs 120). Certain embodiments include operations causing the playback device 110a to pair with another of the one or more playback devices 110 to enable a multi-channel audio environment (e.g., a stereo pair, a bonded zone).

The processors 112a can be further configured to perform operations causing the playback device 110a to synchronize playback of audio data with another of the one or more playback devices 110. As those of ordinary skill in the art will appreciate, during synchronous playback of audio data on a plurality of playback devices, a listener will preferably be unable to perceive time-delay differences between playback of the audio data by the playback device 110a and the other one or more other playback devices 110. Additional details regarding audio playback synchronization among playback devices can be found, for example, in U.S. Pat. No. 8,234,395, which was incorporated by reference above.

In some embodiments, the memory 112b is further configured to store data associated with the playback device 110a, such as one or more zones and/or zone groups of which the playback device 110a is a member, audio sources accessible to the playback device 110a, and/or a playback queue that the playback device 110a (and/or another of the one or more playback devices) can be associated with. The stored data can comprise one or more state variables that are periodically updated and used to describe a state of the playback device 110a. The memory 112b can also include data associated with a state of one or more of the other devices (e.g., the playback devices 110, NMDs 120, control devices 130) of the media playback system 100. In some aspects, for example, the state data is shared during predetermined intervals of time (e.g., every 5 seconds, every 10 seconds, every 60 seconds) among at least a portion of the devices of the media playback system 100, so that one or more of the devices have the most recent data associated with the media playback system 100.

The network interface 112d is configured to facilitate a transmission of data between the playback device 110a and one or more other devices on a data network such as, for example, the links 103 and/or the network 104 (FIG. 1B). The network interface 112d is configured to transmit and receive data corresponding to media content (e.g., audio data, video data, text, photographs) and other signals (e.g., non-transitory signals) comprising digital packet data including an Internet Protocol (IP)-based source address and/or an IP-based destination address. The network interface 112d can parse the digital packet data such that the electronics 112 properly receives and processes the data destined for the playback device 110a.

In the illustrated embodiment of FIG. 1C, the network interface 112d comprises one or more wireless interfaces 112e (referred to hereinafter as “the wireless interface 112e”). The wireless interface 112e (e.g., a suitable interface comprising one or more antennae) can be configured to wirelessly communicate with one or more other devices (e.g., one or more of the other playback devices 110, NMDs 120, and/or control devices 130) that are communicatively coupled to the network 104 (FIG. 1B) in accordance with a suitable wireless communication protocol (e.g., WiFi, Bluetooth, LTE). In some embodiments, the network interface 112d optionally includes a wired interface 112f (e.g., an interface or receptacle configured to receive a network cable such as an Ethernet, a USB-A, USB-C, and/or Thunderbolt cable) configured to communicate over a wired connection with other devices in accordance with a suitable wired communication protocol. In certain embodiments, the network interface 112d includes the wired interface 112f and excludes the wireless interface 112e. In some embodiments, the electronics 112 excludes the network interface 112d altogether and transmits and receives media content and/or other data via another communication path (e.g., the input/output 111).

The audio processing components 112g are configured to process and/or filter data comprising media content received by the electronics 112 (e.g., via the input/output 111 and/or the network interface 112d) to produce output audio signals. In some embodiments, the audio processing components 112g comprise, for example, one or more digital-to-analog converters (DAC), audio preprocessing components, audio enhancement components, a digital signal processors (DSPs), and/or other suitable audio processing components, modules, circuits, etc. In certain embodiments, one or more of the audio processing components 112g can comprise one or more subcomponents of the processors 112a. In some embodiments, the electronics 112 omits the audio processing components 112g. In some aspects, for example, the processors 112a execute instructions stored on the memory 112b to perform audio processing operations to produce the output audio signals.

The amplifiers 112h are configured to receive and amplify the audio output signals produced by the audio processing components 112g and/or the processors 112a. The amplifiers 112h can comprise electronic devices and/or components configured to amplify audio signals to levels sufficient for driving one or more of the transducers 114. In some embodiments, for example, the amplifiers 112h include one or more switching or class-D power amplifiers. In other embodiments, however, the amplifiers include one or more other types of power amplifiers (e.g., linear gain power amplifiers, class-A amplifiers, class-B amplifiers, class-AB amplifiers, class-C amplifiers, class-D amplifiers, class-E amplifiers, class-F amplifiers, class-G and/or class H amplifiers, and/or another suitable type of power amplifier). In certain embodiments, the amplifiers 112h comprise a suitable combination of two or more of the foregoing types of power amplifiers. Moreover, in some embodiments, individual ones of the amplifiers 112h correspond to individual ones of the transducers 114. In other embodiments, however, the electronics 112 includes a single one of the amplifiers 112h configured to output amplified audio signals to a plurality of the transducers 114. In some other embodiments, the electronics 112 omits the amplifiers 112h.

The transducers 114 (e.g., one or more speakers and/or speaker drivers) receive the amplified audio signals from the amplifier 112h and render or output the amplified audio signals as sound (e.g., audible sound waves having a frequency between about 20 Hertz (Hz) and 20 kilohertz (kHz)). In some embodiments, the transducers 114 can comprise a single transducer. In other embodiments, however, the transducers 114 comprise a plurality of audio transducers. In some embodiments, the transducers 114 comprise more than one type of transducer. For example, the transducers 114 can include one or more low frequency transducers (e.g., subwoofers, woofers), mid-range frequency transducers (e.g., mid-range transducers, mid-woofers), and one or more high frequency transducers (e.g., one or more tweeters). As used herein, “low frequency” can generally refer to audible frequencies below about 500 Hz, “mid-range frequency” can generally refer to audible frequencies between about 500 Hz and about 2 kHz, and “high frequency” can generally refer to audible frequencies above 2 kHz. In certain embodiments, however, one or more of the transducers 114 comprise transducers that do not adhere to the foregoing frequency ranges. For example, one of the transducers 114 may comprise a mid-woofer transducer configured to output sound at frequencies between about 200 Hz and about 5 kHz.

By way of illustration, SONOS, Inc. presently offers (or has offered) for sale certain playback devices including, for example, a “SONOS ONE,” “PLAY:1,” “PLAY:3,” “PLAY:5,” “PLAYBAR,” “PLAYBASE,” “CONNECT:AMP,” “CONNECT,” and “SUB.” Other suitable playback devices may additionally or alternatively be used to implement the playback devices of example embodiments disclosed herein. Additionally, one of ordinary skilled in the art will appreciate that a playback device is not limited to the examples described herein or to SONOS product offerings. In some embodiments, for example, one or more playback devices 110 comprises wired or wireless headphones (e.g., over-the-ear headphones, on-ear headphones, in-ear earphones). In other embodiments, one or more of the playback devices 110 comprise a docking station and/or an interface configured to interact with a docking station for personal mobile media playback devices. In certain embodiments, a playback device may be integral to another device or component such as a television, a lighting fixture, or some other device for indoor or outdoor use. In some embodiments, a playback device omits a user interface and/or one or more transducers. For example, FIG. 1D is a block diagram of a playback device 110p comprising the input/output 111 and electronics 112 without the user interface 113 or transducers 114.

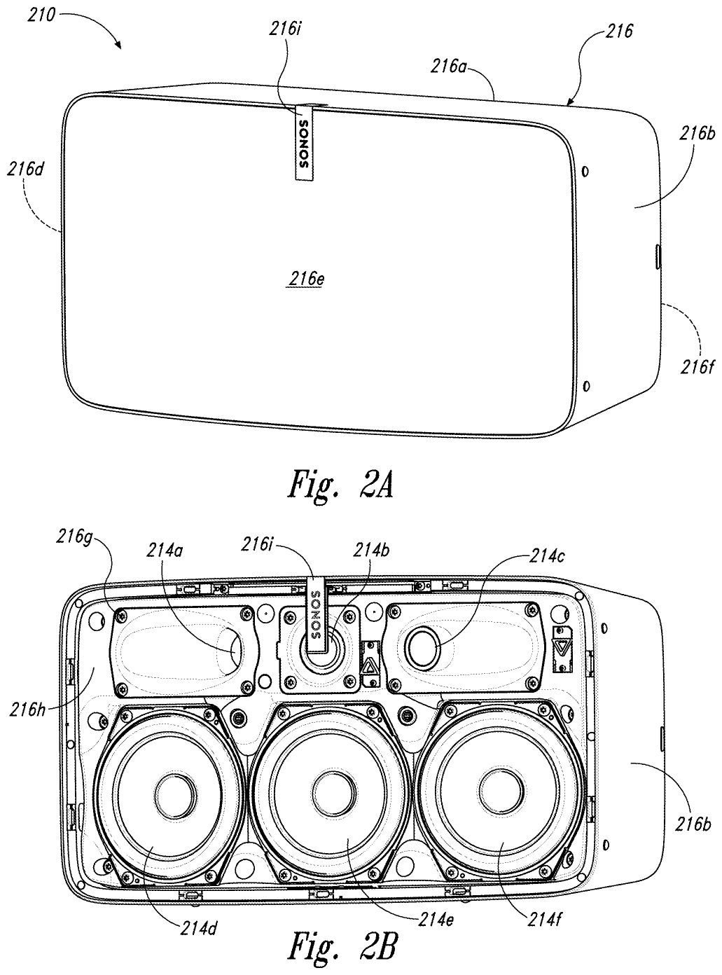

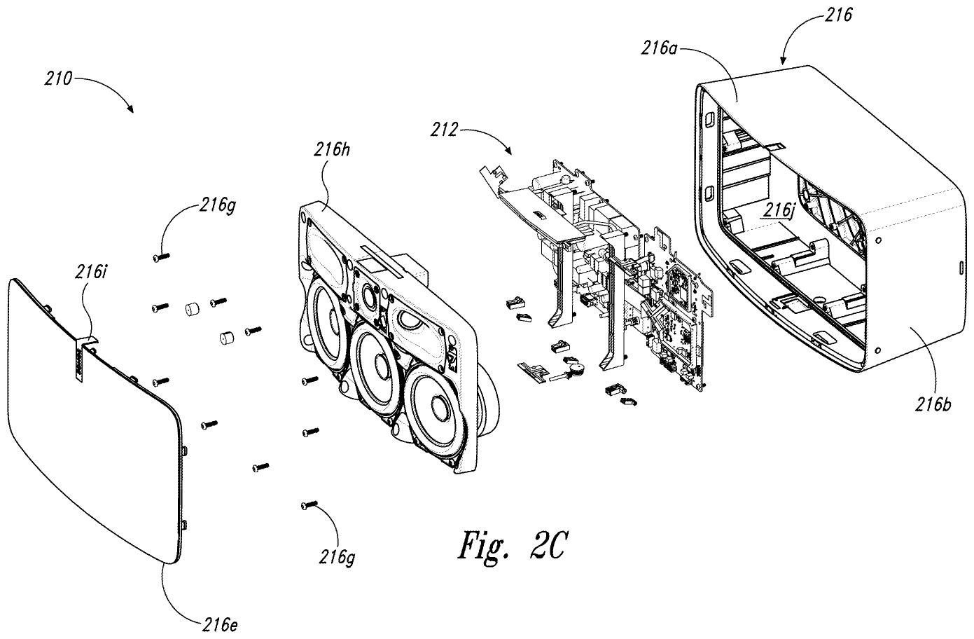

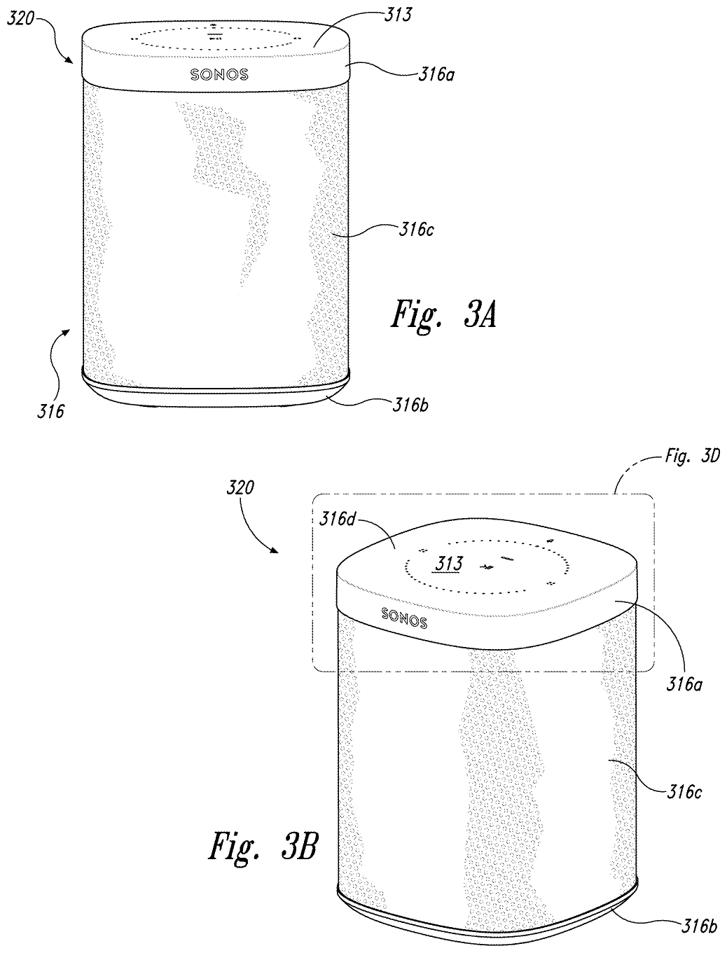

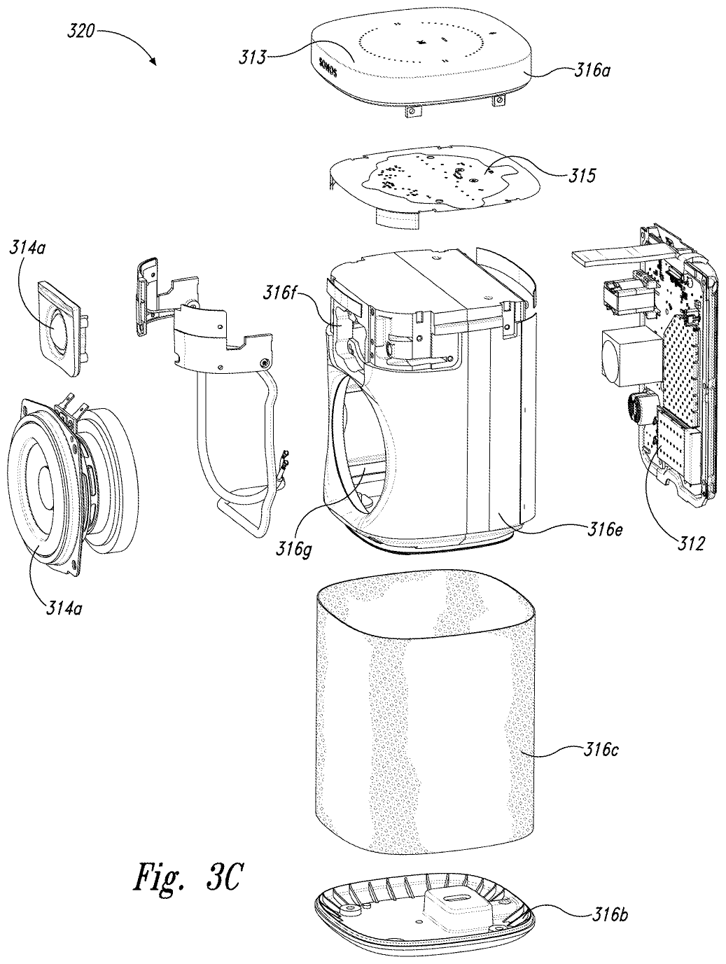

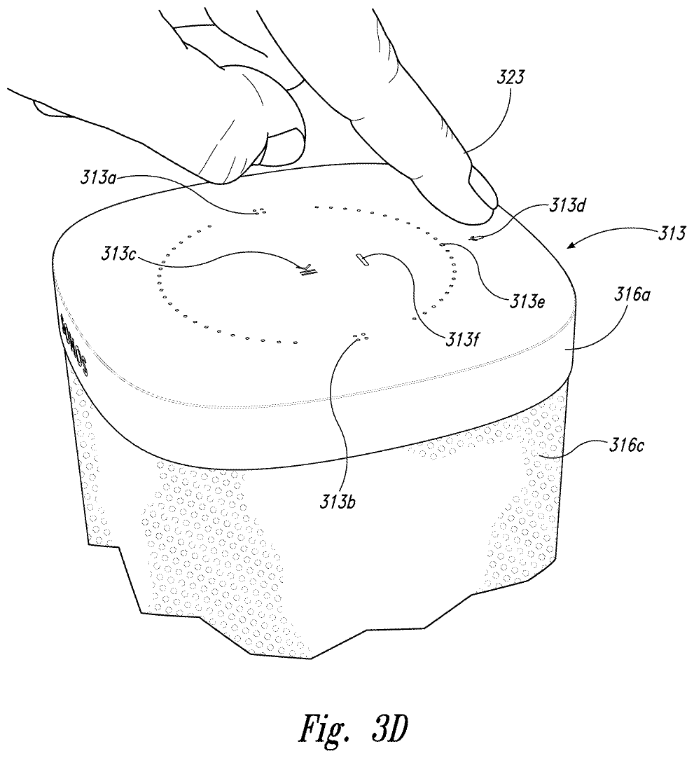

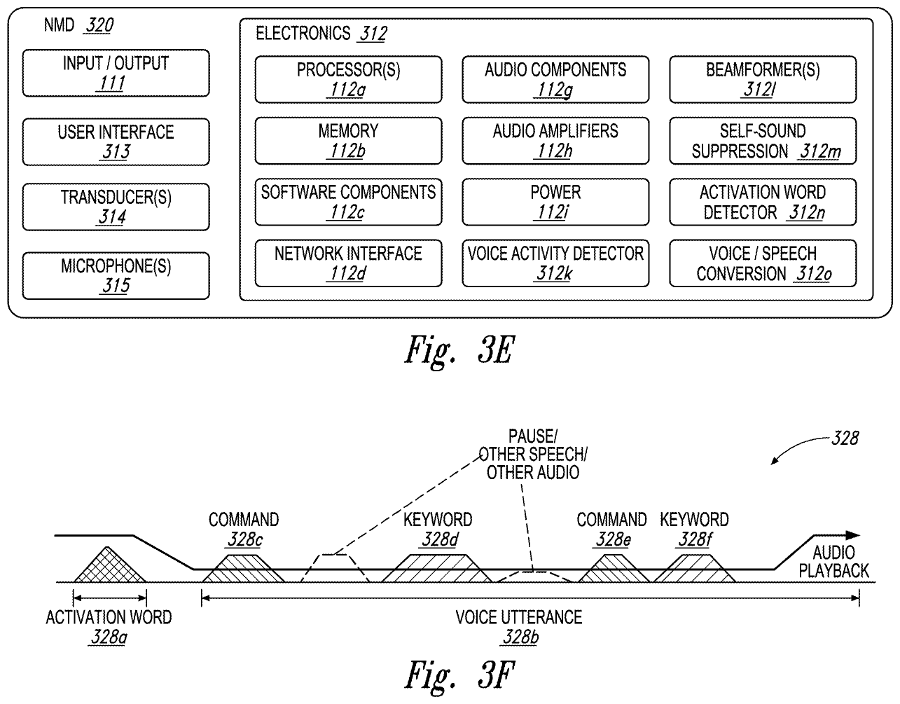

FIG. 1E is a block diagram of a bonded playback device 110q comprising the playback device 110a (FIG. 1C) sonically bonded with the playback device 110i (e.g., a subwoofer) (FIG. 1A). In the illustrated embodiment, the playback devices 110a and 110i are separate ones of the playback devices 110 housed in separate enclosures. In some embodiments, however, the bonded playback device 110q comprises a single enclosure housing both the playback devices 110a and 110i. The bonded playback device 110q can be configured to process and reproduce sound differently than an unbonded playback device (e.g., the playback device 110a of FIG. 1C) and/or paired or bonded playback devices (e.g., the playback devices 110l and 110m of FIG. 1B). In some embodiments, for example, the playback device 110a is full-range playback device configured to render low frequency, mid-range frequency, and high frequency audio content, and the playback device 110i is a subwoofer configured to render low frequency audio content. In some aspects, the playback device 110a, when bonded with the first playback device, is configured to render only the mid-range and high frequency components of a particular audio content, while the playback device 110i renders the low frequency component of the particular audio content. In some embodiments, the bonded playback device 110q includes additional playback devices and/or another bonded playback device. Additional playback device embodiments are described in further detail below with respect to FIGS. 2A-3D.

c. Suitable Network Microphone Devices (NMDs)

FIG. 1F is a block diagram of the NMD 120a (FIGS. 1A and 1B). The NMD 120a includes one or more voice processing components 124 (hereinafter “the voice components 124”) and several components described with respect to the playback device 110a (FIG. 1C) including the processors 112a, the memory 112b, and the microphones 115. The NMD 120a optionally comprises other components also included in the playback device 110a (FIG. 1C), such as the user interface 113 and/or the transducers 114. In some embodiments, the NMD 120a is configured as a media playback device (e.g., one or more of the playback devices 110), and further includes, for example, one or more of the audio processing components 112g (FIG. 1C), the transducers 114, and/or other playback device components. In certain embodiments, the NMD 120a comprises an Internet of Things (IoT) device such as, for example, a thermostat, alarm panel, fire and/or smoke detector, etc. In some embodiments, the NMD 120a comprises the microphones 115, the voice processing 124, and only a portion of the components of the electronics 112 described above with respect to FIG. 1B. In some aspects, for example, the NMD 120a includes the processor 112a and the memory 112b (FIG. 1B), while omitting one or more other components of the electronics 112. In some embodiments, the NMD 120a includes additional components (e.g., one or more sensors, cameras, thermometers, barometers, hygrometers).

In some embodiments, an NMD can be integrated into a playback device. FIG. 1G is a block diagram of a playback device 110r comprising an NMD 120d. The playback device 110r can comprise many or all of the components of the playback device 110a and further include the microphones 115 and voice processing 124 (FIG. 1F). The playback device 110r optionally includes an integrated control device 130c. The control device 130c can comprise, for example, a user interface (e.g., the user interface 113 of FIG. 1B) configured to receive user input (e.g., touch input, voice input) without a separate control device. In other embodiments, however, the playback device 110r receives commands from another control device (e.g., the control device 130a of FIG. 1B). Additional NMD embodiments are described in further detail below with respect to FIGS. 3A-3F.

Referring again to FIG. 1F, the microphones 115 are configured to acquire, capture, and/or receive sound from an environment (e.g., the environment 101 of FIG. 1A) and/or a room in which the NMD 120a is positioned. The received sound can include, for example, vocal utterances, audio played back by the NMD 120a and/or another playback device, background voices, ambient sounds, etc. The microphones 115 convert the received sound into electrical signals to produce microphone data. The voice processing 124 receives and analyzes the microphone data to determine whether a voice input is present in the microphone data. The voice input can comprise, for example, an activation word followed by an utterance including a user request. As those of ordinary skill in the art will appreciate, an activation word is a word or other audio cue that signifying a user voice input. For instance, in querying the AMAZON® VAS, a user might speak the activation word “Alexa.” Other examples include “Ok, Google” for invoking the GOOGLE® VAS and “Hey, Siri” for invoking the APPLE® VAS.

After detecting the activation word, voice processing 124 monitors the microphone data for an accompanying user request in the voice input. The user request may include, for example, a command to control a third-party device, such as a thermostat (e.g., NEST® thermostat), an illumination device (e.g., a PHILIPS HUE® lighting device), or a media playback device (e.g., a Sonos® playback device). For example, a user might speak the activation word “Alexa” followed by the utterance “set the thermostat to 68 degrees” to set a temperature in a home (e.g., the environment 101 of FIG. 1A). The user might speak the same activation word followed by the utterance “turn on the living room” to turn on illumination devices in a living room area of the home. The user may similarly speak an activation word followed by a request to play a particular song, an album, or a playlist of music on a playback device in the home. Additional description regarding receiving and processing voice input data can be found in further detail below with respect to FIGS. 3A-3F.

d. Suitable Control Devices

FIG. 1H is a partially schematic diagram of the control device 130a (FIGS. 1A and 1B). As used herein, the term “control device” can be used interchangeably with “controller” or “control system.” Among other features, the control device 130a is configured to receive user input related to the media playback system 100 and, in response, cause one or more devices in the media playback system 100 to perform an action(s) or operation(s) corresponding to the user input. In the illustrated embodiment, the control device 130a comprises a smartphone (e.g., an iPhone™, an Android phone) on which media playback system controller application software is installed. In some embodiments, the control device 130a comprises, for example, a tablet (e.g., an iPad™), a computer (e.g., a laptop computer, a desktop computer), and/or another suitable device (e.g., a television, an automobile audio head unit, an IoT device). In certain embodiments, the control device 130a comprises a dedicated controller for the media playback system 100. In other embodiments, as described above with respect to FIG. 1G, the control device 130a is integrated into another device in the media playback system 100 (e.g., one more of the playback devices 110, NMDs 120, and/or other suitable devices configured to communicate over a network).

The control device 130a includes electronics 132, a user interface 133, one or more speakers 134, and one or more microphones 135. The electronics 132 comprise one or more processors 132a (referred to hereinafter as “the processors 132a”), a memory 132b, software components 132c, and a network interface 132d. The processor 132a can be configured to perform functions relevant to facilitating user access, control, and configuration of the media playback system 100. The memory 132b can comprise data storage that can be loaded with one or more of the software components executable by the processor 302 to perform those functions. The software components 132c can comprise applications and/or other executable software configured to facilitate control of the media playback system 100. The memory 112b can be configured to store, for example, the software components 132c, media playback system controller application software, and/or other data associated with the media playback system 100 and the user.

The network interface 132d is configured to facilitate network communications between the control device 130a and one or more other devices in the media playback system 100, and/or one or more remote devices. In some embodiments, the network interface 132d is configured to operate according to one or more suitable communication industry standards (e.g., infrared, radio, wired standards including IEEE 802.3, wireless standards including IEEE 802.11a, 802.11b, 802.11g, 802.11n, 802.11ac, 802.15, 4G, LTE). The network interface 132d can be configured, for example, to transmit data to and/or receive data from the playback devices 110, the NMDs 120, other ones of the control devices 130, one of the computing devices 106 of FIG. 1B, devices comprising one or more other media playback systems, etc. The transmitted and/or received data can include, for example, playback device control commands, state variables, playback zone and/or zone group configurations. For instance, based on user input received at the user interface 133, the network interface 132d can transmit a playback device control command (e.g., volume control, audio playback control, audio content selection) from the control device 304 to one or more of playback devices. The network interface 132d can also transmit and/or receive configuration changes such as, for example, adding/removing one or more playback devices to/from a zone, adding/removing one or more zones to/from a zone group, forming a bonded or consolidated player, separating one or more playback devices from a bonded or consolidated player, among others. Additional description of zones and groups can be found below with respect to FIGS. 1-I through 1M.

The user interface 133 is configured to receive user input and can facilitate control of the media playback system 100. The user interface 133 includes media content art 133a (e.g., album art, lyrics, videos), a playback status indicator 133b (e.g., an elapsed and/or remaining time indicator), media content information region 133c, a playback control region 133d, and a zone indicator 133e. The media content information region 133c can include a display of relevant information (e.g., title, artist, album, genre, release year) about media content currently playing and/or media content in a queue or playlist. The playback control region 133d can include selectable (e.g., via touch input and/or via a cursor or another suitable selector) icons to cause one or more playback devices in a selected playback zone or zone group to perform playback actions such as, for example, play or pause, fast forward, rewind, skip to next, skip to previous, enter/exit shuffle mode, enter/exit repeat mode, enter/exit cross fade mode, etc. The playback control region 133d may also include selectable icons to modify equalization settings, playback volume, and/or other suitable playback actions. In the illustrated embodiment, the user interface 133 comprises a display presented on a touch screen interface of a smartphone (e.g., an iPhone™, an Android phone). In some embodiments, however, user interfaces of varying formats, styles, and interactive sequences may alternatively be implemented on one or more network devices to provide comparable control access to a media playback system.

The one or more speakers 134 (e.g., one or more transducers) can be configured to output sound to the user of the control device 130a. In some embodiments, the one or more speakers comprise individual transducers configured to correspondingly output low frequencies, mid-range frequencies, and/or high frequencies. In some aspects, for example, the control device 130a is configured as a playback device (e.g., one of the playback devices 110). Similarly, in some embodiments the control device 130a is configured as an NMD (e.g., one of the NMDs 120), receiving voice commands and other sounds via the one or more microphones 135.

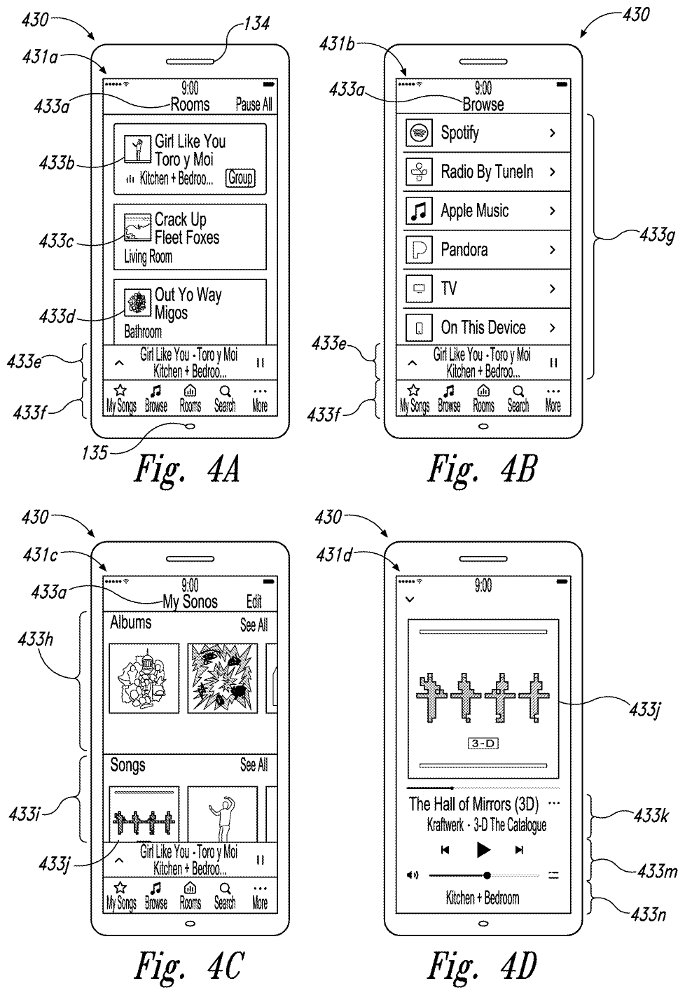

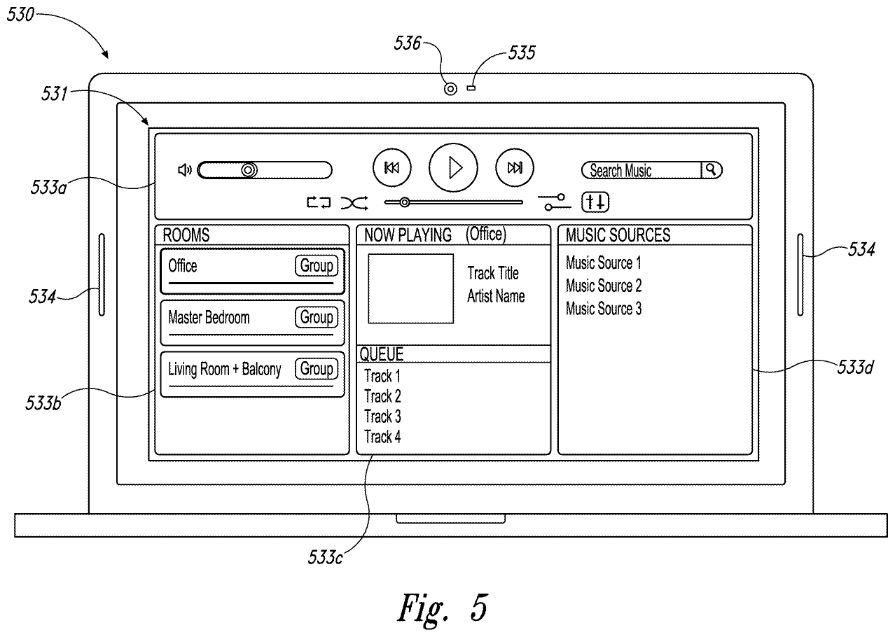

The one or more microphones 135 can comprise, for example, one or more condenser microphones, electret condenser microphones, dynamic microphones, and/or other suitable types of microphones or transducers. In some embodiments, two or more of the microphones 135 are arranged to capture location information of an audio source (e.g., voice, audible sound) and/or configured to facilitate filtering of background noise. Moreover, in certain embodiments, the control device 130a is configured to operate as playback device and an NMD. In other embodiments, however, the control device 130a omits the one or more speakers 134 and/or the one or more microphones 135. For instance, the control device 130a may comprise a device (e.g., a thermostat, an IoT device, a network device) comprising a portion of the electronics 132 and the user interface 133 (e.g., a touch screen) without any speakers or microphones. Additional control device embodiments are described in further detail below with respect to FIGS. 4A-4D and 5.

e. Suitable Playback Device Configurations

FIGS. 1-1 through 1M show example configurations of playback devices in zones and zone groups. Referring first to FIG. 1M, in one example, a single playback device may belong to a zone. For example, the playback device 110g in the second bedroom 101c (FIG. 1A) may belong to Zone C. In some implementations described below, multiple playback devices may be “bonded” to form a “bonded pair” which together form a single zone. For example, the playback device 110l (e.g., a left playback device) can be bonded to the playback device 110l (e.g., a left playback device) to form Zone A. Bonded playback devices may have different playback responsibilities (e.g., channel responsibilities). In another implementation described below, multiple playback devices may be merged to form a single zone. For example, the playback device 110h (e.g., a front playback device) may be merged with the playback device 110i (e.g., a subwoofer), and the playback devices 110j and 110k (e.g., left and right surround speakers, respectively) to form a single Zone D. In another example, the playback devices 110g and 110h can be merged to form a merged group or a zone group 108b. The merged playback devices 110g and 110h may not be specifically assigned different playback responsibilities. That is, the merged playback devices 110h and 110i may, aside from playing audio data in synchrony, each play audio data as they would if they were not merged.

Each zone in the media playback system 100 may be provided for control as a single user interface (UI) entity. For example, Zone A may be provided as a single entity named Master Bathroom. Zone B may be provided as a single entity named Master Bedroom. Zone C may be provided as a single entity named Second Bedroom.

Playback devices that are bonded may have different playback responsibilities, such as responsibilities for certain audio channels. For example, as shown in FIG. 1-I, the playback devices 110l and 110m may be bonded so as to produce or enhance a stereo effect of audio data. In this example, the playback device 110l may be configured to play a left channel audio component, while the playback device 110k may be configured to play a right channel audio component. In some implementations, such stereo bonding may be referred to as “pairing.”

Additionally, bonded playback devices may have additional and/or different respective speaker drivers. As shown in FIG. 1J, the playback device 110h named Front may be bonded with the playback device 110i named SUB. The Front device 110h can be configured to render a range of mid to high frequencies and the SUB device 110i can be configured render low frequencies. When unbonded, however, the Front device 110h can be configured render a full range of frequencies. As another example, FIG. 1K shows the Front and SUB devices 110h and 110i further bonded with Left and Right playback devices 110j and 110k, respectively. In some implementations, the Right and Left devices 110j and 102k can be configured to form surround or “satellite” channels of a home theater system. The bonded playback devices 110h, 110i, 110j, and 110k may form a single Zone D (FIG. 1M).

Playback devices that are merged may not have assigned playback responsibilities, and may each render the full range of audio data the respective playback device is capable of. Nevertheless, merged devices may be represented as a single UI entity (i.e., a zone, as discussed above). For instance, the playback devices 110a and 110n the master bathroom have the single UI entity of Zone A. In one embodiment, the playback devices 110a and 110n may each output the full range of audio data each respective playback devices 110a and 110n are capable of, in synchrony.

In some embodiments, an NMD is bonded or merged with another device so as to form a zone. For example, the NMD 120b may be bonded with the playback device 110e, which together form Zone F, named Living Room. In other embodiments, a stand-alone network microphone device may be in a zone by itself. In other embodiments, however, a stand-alone network microphone device may not be associated with a zone. Additional details regarding associating network microphone devices and playback devices as designated or default devices may be found, for example, in previously referenced U.S. patent application Ser. No. 15/438,749.

Zones of individual, bonded, and/or merged devices may be grouped to form a zone group. For example, referring to FIG. 1M, Zone A may be grouped with Zone B to form a zone group 108a that includes the two zones. Similarly, Zone G may be grouped with Zone H to form the zone group 108b. As another example, Zone A may be grouped with one or more other Zones C-I. The Zones A-I may be grouped and ungrouped in numerous ways. For example, three, four, five, or more (e.g., all) of the Zones A-I may be grouped. When grouped, the zones of individual and/or bonded playback devices may play back audio in synchrony with one another, as described in previously referenced U.S. Pat. No. 8,234,395. Playback devices may be dynamically grouped and ungrouped to form new or different groups that synchronously play back audio data.

In various implementations, the zones in an environment may be the default name of a zone within the group or a combination of the names of the zones within a zone group. For example, Zone Group 108b can have be assigned a name such as “Dining+Kitchen”, as shown in FIG. 1M. In some embodiments, a zone group may be given a unique name selected by a user.

Certain data may be stored in a memory of a playback device (e.g., the memory 112b of FIG. 1C) as one or more state variables that are periodically updated and used to describe the state of a playback zone, the playback device(s), and/or a zone group associated therewith. The memory may also include the data associated with the state of the other devices of the media system, and shared from time to time among the devices so that one or more of the devices have the most recent data associated with the system.

In some embodiments, the memory may store instances of various variable types associated with the states. Variables instances may be stored with identifiers (e.g., tags) corresponding to type. For example, certain identifiers may be a first type “a1” to identify playback device(s) of a zone, a second type “b1” to identify playback device(s) that may be bonded in the zone, and a third type “c1” to identify a zone group to which the zone may belong. As a related example, identifiers associated with the second bedroom 101c may indicate that the playback device is the only playback device of the Zone C and not in a zone group. Identifiers associated with the Den may indicate that the Den is not grouped with other zones but includes bonded playback devices 110h-110k. Identifiers associated with the Dining Room may indicate that the Dining Room is part of the Dining+Kitchen zone group 108b and that devices 110b and 110d are grouped (FIG. 1L). Identifiers associated with the Kitchen may indicate the same or similar information by virtue of the Kitchen being part of the Dining+Kitchen zone group 108b. Other example zone variables and identifiers are described below.

In yet another example, the media playback system 100 may variables or identifiers representing other associations of zones and zone groups, such as identifiers associated with Areas, as shown in FIG. 1M. An area may involve a cluster of zone groups and/or zones not within a zone group. For instance, FIG. 1M shows an Upper Area 109a including Zones A-D, and a Lower Area 109b including Zones E-I. In one aspect, an Area may be used to invoke a cluster of zone groups and/or zones that share one or more zones and/or zone groups of another cluster. In another aspect, this differs from a zone group, which does not share a zone with another zone group. Further examples of techniques for implementing Areas may be found, for example, in U.S. application Ser. No. 15/682,506 filed Aug. 21, 2017 and titled “Room Association Based on Name,” and U.S. Pat. No. 8,483,853 filed Sep. 11, 2007, and titled “Controlling and manipulating groupings in a multi-zone media system.” Each of these applications is incorporated herein by reference in its entirety. In some embodiments, the media playback system 100 may not implement Areas, in which case the system may not store variables associated with Areas.

### III. Example Systems and Devices

FIG. 2A is a front isometric view of a playback device 210 configured in accordance with aspects of the disclosed technology. FIG. 2B is a front isometric view of the playback device 210 without a grille 216e. FIG. 2C is an exploded view of the playback device 210. Referring to FIGS. 2A-2C together, the playback device 210 comprises a housing 216 that includes an upper portion 216a, a right or first side portion 216b, a lower portion 216c, a left or second side portion 216d, the grille 216e, and a rear portion 216f. A plurality of fasteners 216g (e.g., one or more screws, rivets, clips) attaches a frame 216h to the housing 216. A cavity 216j (FIG. 2C) in the housing 216 is configured to receive the frame 216h and electronics 212. The frame 216h is configured to carry a plurality of transducers 214 (identified individually in FIG. 2B as transducers 214a-f). The electronics 212 (e.g., the electronics 112 of FIG. 1C) is configured to receive audio data from an audio source and send electrical signals corresponding to the audio data to the transducers 214 for playback.

The transducers 214 are configured to receive the electrical signals from the electronics 112, and further configured to convert the received electrical signals into audible sound during playback. For instance, the transducers 214a-c (e.g., tweeters) can be configured to output high frequency sound (e.g., sound waves having a frequency greater than about 2 kHz). The transducers 214d-f (e.g., mid-woofers, woofers, midrange speakers) can be configured output sound at frequencies lower than the transducers 214a-c (e.g., sound waves having a frequency lower than about 2 kHz). In some embodiments, the playback device 210 includes a number of transducers different than those illustrated in FIGS. 2A-2C. For example, as described in further detail below with respect to FIGS. 3A-3C, the playback device 210 can include fewer than six transducers (e.g., one, two, three). In other embodiments, however, the playback device 210 includes more than six transducers (e.g., nine, ten). Moreover, in some embodiments, all or a portion of the transducers 214 are configured to operate as a phased array to desirably adjust (e.g., narrow or widen) a radiation pattern of the transducers 214, thereby altering a user's perception of the sound emitted from the playback device 210.

In the illustrated embodiment of FIGS. 2A-2C, a filter 216i is axially aligned with the transducer 214b. The filter 216i can be configured to desirably attenuate a predetermined range of frequencies that the transducer 214b outputs to improve sound quality and a perceived sound stage output collectively by the transducers 214. In some embodiments, however, the playback device 210 omits the filter 216i. In other embodiments, the playback device 210 includes one or more additional filters aligned with the transducers 214b and/or at least another of the transducers 214.

FIGS. 3A and 3B are front and right isometric side views, respectively, of an NMD 320 configured in accordance with embodiments of the disclosed technology. FIG. 3C is an exploded view of the NMD 320. FIG. 3D is an enlarged view of a portion of FIG. 3B including a user interface 313 of the NMD 320. Referring first to FIGS. 3A-3C, the NMD 320 includes a housing 316 comprising an upper portion 316a, a lower portion 316b and an intermediate portion 316c (e.g., a grille). A plurality of ports, holes or apertures 316d in the upper portion 316a allow sound to pass through to one or more microphones 315 (FIG. 3C) positioned within the housing 316. The one or more microphones 315 are configured to received sound via the apertures 316d and produce electrical signals based on the received sound. In the illustrated embodiment, a frame 316e (FIG. 3C) of the housing 316 surrounds cavities 316f and 316g configured to house, respectively, a first transducer 314a (e.g., a tweeter) and a second transducer 314b (e.g., a mid-woofer, a midrange speaker, a woofer). In other embodiments, however, the NMD 320 includes a single transducer, or more than two (e.g., two, five, six) transducers. In certain embodiments, the NMD 320 omits the transducers 314a and 314b altogether.

Electronics 312 (FIG. 3C) includes components configured to drive the transducers 314a and 314b, and further configured to analyze audio information corresponding to the electrical signals produced by the one or more microphones 315. In some embodiments, for example, the electronics 312 comprises many or all of the components of the electronics 112 described above with respect to FIG. 1C. In certain embodiments, the electronics 312 includes components described above with respect to FIG. 1F such as, for example, the one or more processors 112a, the memory 112b, the software components 112c, the network interface 112d, etc. In some embodiments, the electronics 312 includes additional suitable components (e.g., proximity or other sensors).

Referring to FIG. 3D, the user interface 313 includes a plurality of control surfaces (e.g., buttons, knobs, capacitive surfaces) including a first control surface 313a (e.g., a previous control), a second control surface 313b (e.g., a next control), and a third control surface 313c (e.g., a play and/or pause control). A fourth control surface 313d is configured to receive touch input corresponding to activation and deactivation of the one or microphones 315. A first indicator 313e (e.g., one or more light emitting diodes (LEDs) or another suitable illuminator) can be configured to illuminate only when the one or more microphones 315 are activated. A second indicator 313f (e.g., one or more LEDs) can be configured to remain solid during normal operation and to blink or otherwise change from solid to indicate a detection of voice activity. In some embodiments, the user interface 313 includes additional or fewer control surfaces and illuminators. In one embodiment, for example, the user interface 313 includes the first indicator 313e, omitting the second indicator 313f. Moreover, in certain embodiments, the NMD 320 comprises a playback device and a control device, and the user interface 313 comprises the user interface of the control device.

Referring to FIGS. 3A-3D together, the NMD 320 is configured to receive voice commands from one or more adjacent users via the one or more microphones 315. As described above with respect to FIG. 1B, the one or more microphones 315 can acquire, capture, or record sound in a vicinity (e.g., a region within 10 m or less of the NMD 320) and transmit electrical signals corresponding to the recorded sound to the electronics 312. The electronics 312 can process the electrical signals and can analyze the resulting audio data to determine a presence of one or more voice commands (e.g., one or more activation words). In some embodiments, for example, after detection of one or more suitable voice commands, the NMD 320 is configured to transmit a portion of the recorded audio data to another device and/or a remote server (e.g., one or more of the computing devices 106 of FIG. 1B) for further analysis. The remote server can analyze the audio data, determine an appropriate action based on the voice command, and transmit a message to the NMD 320 to perform the appropriate action. For instance, a user may speak “Sonos, play Michael Jackson.” The NMD 320 can, via the one or more microphones 315, record the user's voice utterance, determine the presence of a voice command, and transmit the audio data having the voice command to a remote server (e.g., one or more of the remote computing devices 106 of FIG. 1B, one or more servers of a VAS and/or another suitable service). The remote server can analyze the audio data and determine an action corresponding to the command. The remote server can then transmit a command to the NMD 320 to perform the determined action (e.g., play back audio content related to Michael Jackson). The NMD 320 can receive the command and play back the audio content related to Michael Jackson from a media content source. As described above with respect to FIG. 1B, suitable content sources can include a device or storage communicatively coupled to the NMD 320 via a LAN (e.g., the network 104 of FIG. 1B), a remote server (e.g., one or more of the remote computing devices 106 of FIG. 1B), etc. In certain embodiments, however, the NMD 320 determines and/or performs one or more actions corresponding to the one or more voice commands without intervention or involvement of an external device, computer, or server.

FIG. 3E is a functional block diagram showing additional features of the NMD 320 in accordance with aspects of the disclosure. The NMD 320 includes components configured to facilitate voice command capture including voice activity detector component(s) 312k, beam former components 312l, acoustic echo cancellation (AEC) and/or self-sound suppression components 312m, activation word detector components 312n, and voice/speech conversion components 312o (e.g., voice-to-text and text-to-voice). In the illustrated embodiment of FIG. 3E, the foregoing components 312k-312o are shown as separate components. In some embodiments, however, one or more of the components 312k-312o are subcomponents of the processors 112a.

The beamforming and self-sound suppression components 312l and 312m are configured to detect an audio signal and determine aspects of voice input represented in the detected audio signal, such as the direction, amplitude, frequency spectrum, etc. The voice activity detector activity components 312k are operably coupled with the beamforming and AEC components 312l and 312m and are configured to determine a direction and/or directions from which voice activity is likely to have occurred in the detected audio signal. Potential speech directions can be identified by monitoring metrics which distinguish speech from other sounds. Such metrics can include, for example, energy within the speech band relative to background noise and entropy within the speech band, which is measure of spectral structure. As those of ordinary skill in the art will appreciate, speech typically has a lower entropy than most common background noise.

The activation word detector components 312n are configured to monitor and analyze received audio to determine if any activation words (e.g., wake words) are present in the received audio. The activation word detector components 312n may analyze the received audio using an activation word detection algorithm. If the activation word detector 312n detects an activation word, the NMD 320 may process voice input contained in the received audio. Example activation word detection algorithms accept audio as input and provide an indication of whether an activation word is present in the audio. Many first- and third-party activation word detection algorithms are known and commercially available. For instance, operators of a voice service may make their algorithm available for use in third-party devices. Alternatively, an algorithm may be trained to detect certain activation words. In some embodiments, the activation word detector 312n runs multiple activation word detection algorithms on the received audio simultaneously (or substantially simultaneously). As noted above, different voice services (e.g. AMAZON's ALEXA®, APPLE's SIRI®, or MICROSOFT's CORTANA®) can each use a different activation word for invoking their respective voice service. To support multiple services, the activation word detector 312n may run the received audio through the activation word detection algorithm for each supported voice service in parallel.

The speech/text conversion components 312o may facilitate processing by converting speech in the voice input to text. In some embodiments, the electronics 312 can include voice recognition software that is trained to a particular user or a particular set of users associated with a household. Such voice recognition software may implement voice-processing algorithms that are tuned to specific voice profile(s). Tuning to specific voice profiles may require less computationally intensive algorithms than traditional voice activity services, which typically sample from a broad base of users and diverse requests that are not targeted to media playback systems.

FIG. 3F is a schematic diagram of an example voice input 328 captured by the NMD 320 in accordance with aspects of the disclosure. The voice input 328 can include a activation word portion 328a and a voice utterance portion 328b. In some embodiments, the activation word 557a can be a known activation word, such as “Alexa,” which is associated with AMAZON's ALEXA®. In other embodiments, however, the voice input 328 may not include a activation word. In some embodiments, a network microphone device may output an audible and/or visible response upon detection of the activation word portion 328a. In addition or alternately, an NMB may output an audible and/or visible response after processing a voice input and/or a series of voice inputs.

The voice utterance portion 328b may include, for example, one or more spoken commands (identified individually as a first command 328c and a second command 328e) and one or more spoken keywords (identified individually as a first keyword 328d and a second keyword 328f). In one example, the first command 328c can be a command to play music, such as a specific song, album, playlist, etc. In this example, the keywords may be one or words identifying one or more zones in which the music is to be played, such as the Living Room and the Dining Room shown in FIG. 1A. In some examples, the voice utterance portion 328b can include other information, such as detected pauses (e.g., periods of non-speech) between words spoken by a user, as shown in FIG. 3F. The pauses may demarcate the locations of separate commands, keywords, or other information spoke by the user within the voice utterance portion 328b.

In some embodiments, the media playback system 100 is configured to temporarily reduce the volume of audio data that it is playing while detecting the activation word portion 557a. The media playback system 100 may restore the volume after processing the voice input 328, as shown in FIG. 3F. Such a process can be referred to as ducking, examples of which are disclosed in U.S. patent application Ser. No. 15/438,749, incorporated by reference herein in its entirety.

FIGS. 4A-4D are schematic diagrams of a control device 430 (e.g., the control device 130a of FIG. 1H, a smartphone, a tablet, a dedicated control device, an IoT device, and/or another suitable device) showing corresponding user interface displays in various states of operation. A first user interface display 431a (FIG. 4A) includes a display name 433a (i.e., “Rooms”). A selected group region 433b displays audio content information (e.g., artist name, track name, album art) of audio content played back in the selected group and/or zone. Group regions 433c and 433d display corresponding group and/or zone name, and audio content information audio content played back or next in a playback queue of the respective group or zone. An audio content region 433e includes information related to audio content in the selected group and/or zone (i.e., the group and/or zone indicated in the selected group region 433b). A lower display region 433f is configured to receive touch input to display one or more other user interface displays. For example, if a user selects “Browse” in the lower display region 433f, the control device 430 can be configured to output a second user interface display 431b (FIG. 4B) comprising a plurality of music services 433g (e.g., Spotify, Radio by Tunein, Apple Music, Pandora, Amazon, TV, local music, line-in) through which the user can browse and from which the user can select media content for play back via one or more playback devices (e.g., one of the playback devices 110 of FIG. 1A). Alternatively, if the user selects “My Sonos” in the lower display region 433f, the control device 430 can be configured to output a third user interface display 431c (FIG. 4C). A first media content region 433h can include graphical representations (e.g., album art) corresponding to individual albums, stations, or playlists. A second media content region 433i can include graphical representations (e.g., album art) corresponding to individual songs, tracks, or other media content. If the user selections a graphical representation 433j (FIG. 4C), the control device 430 can be configured to begin play back of audio content corresponding to the graphical representation 433j and output a fourth user interface display 431d fourth user interface display 431d includes an enlarged version of the graphical representation 433j, media content information 433k (e.g., track name, artist, album), transport controls 433m (e.g., play, previous, next, pause, volume), and indication 433n of the currently selected group and/or zone name.

FIG. 5 is a schematic diagram of a control device 530 (e.g., a laptop computer, a desktop computer). The control device 530 includes transducers 534, a microphone 535, and a camera 536. A user interface 531 includes a transport control region 533a, a playback status region 533b, a playback zone region 533c, a playback queue region 533d, and a media content source region 533e. The transport control region comprises one or more controls for controlling media playback including, for example, volume, previous, play/pause, next, repeat, shuffle, track position, crossfade, equalization, etc. The audio content source region 533e includes a listing of one or more media content sources from which a user can select media items for play back and/or adding to a playback queue.

The playback zone region 533b can include representations of playback zones within the media playback system 100 (FIGS. 1A and 1B). In some embodiments, the graphical representations of playback zones may be selectable to bring up additional selectable icons to manage or configure the playback zones in the media playback system, such as a creation of bonded zones, creation of zone groups, separation of zone groups, renaming of zone groups, etc. In the illustrated embodiment, a “group” icon is provided within each of the graphical representations of playback zones. The “group” icon provided within a graphical representation of a particular zone may be selectable to bring up options to select one or more other zones in the media playback system to be grouped with the particular zone. Once grouped, playback devices in the zones that have been grouped with the particular zone can be configured to play audio data in synchrony with the playback device(s) in the particular zone. Analogously, a “group” icon may be provided within a graphical representation of a zone group. In the illustrated embodiment, the “group” icon may be selectable to bring up options to deselect one or more zones in the zone group to be removed from the zone group. In some embodiments, the control device 530 includes other interactions and implementations for grouping and ungrouping zones via the user interface 531. In certain embodiments, the representations of playback zones in the playback zone region 533b can be dynamically updated as playback zone or zone group configurations are modified.

The playback status region 533c includes graphical representations of audio content that is presently being played, previously played, or scheduled to play next in the selected playback zone or zone group. The selected playback zone or zone group may be visually distinguished on the user interface, such as within the playback zone region 533b and/or the playback queue region 533d. The graphical representations may include track title, artist name, album name, album year, track length, and other relevant information that may be useful for the user to know when controlling the media playback system 100 via the user interface 531.

The playback queue region 533d includes graphical representations of audio content in a playback queue associated with the selected playback zone or zone group. In some embodiments, each playback zone or zone group may be associated with a playback queue containing information corresponding to zero or more audio items for playback by the playback zone or zone group. For instance, each audio item in the playback queue may comprise a uniform resource identifier (URI), a uniform resource locator (URL) or some other identifier that may be used by a playback device in the playback zone or zone group to find and/or retrieve the audio item from a local audio content source or a networked audio content source, possibly for playback by the playback device. In some embodiments, for example, a playlist can be added to a playback queue, in which information corresponding to each audio item in the playlist may be added to the playback queue. In some embodiments, audio items in a playback queue may be saved as a playlist. In certain embodiments, a playback queue may be empty, or populated but “not in use” when the playback zone or zone group is playing continuously streaming audio content, such as Internet radio that may continue to play until otherwise stopped, rather than discrete audio items that have playback durations. In some embodiments, a playback queue can include Internet radio and/or other streaming audio content items and be “in use” when the playback zone or zone group is playing those items.

When playback zones or zone groups are “grouped” or “ungrouped,” playback queues associated with the affected playback zones or zone groups may be cleared or re-associated. For example, if a first playback zone including a first playback queue is grouped with a second playback zone including a second playback queue, the established zone group may have an associated playback queue that is initially empty, that contains audio items from the first playback queue (such as if the second playback zone was added to the first playback zone), that contains audio items from the second playback queue (such as if the first playback zone was added to the second playback zone), or a combination of audio items from both the first and second playback queues. Subsequently, if the established zone group is ungrouped, the resulting first playback zone may be re-associated with the previous first playback queue, or be associated with a new playback queue that is empty or contains audio items from the playback queue associated with the established zone group before the established zone group was ungrouped. Similarly, the resulting second playback zone may be re-associated with the previous second playback queue, or be associated with a new playback queue that is empty, or contains audio items from the playback queue associated with the established zone group before the established zone group was ungrouped.

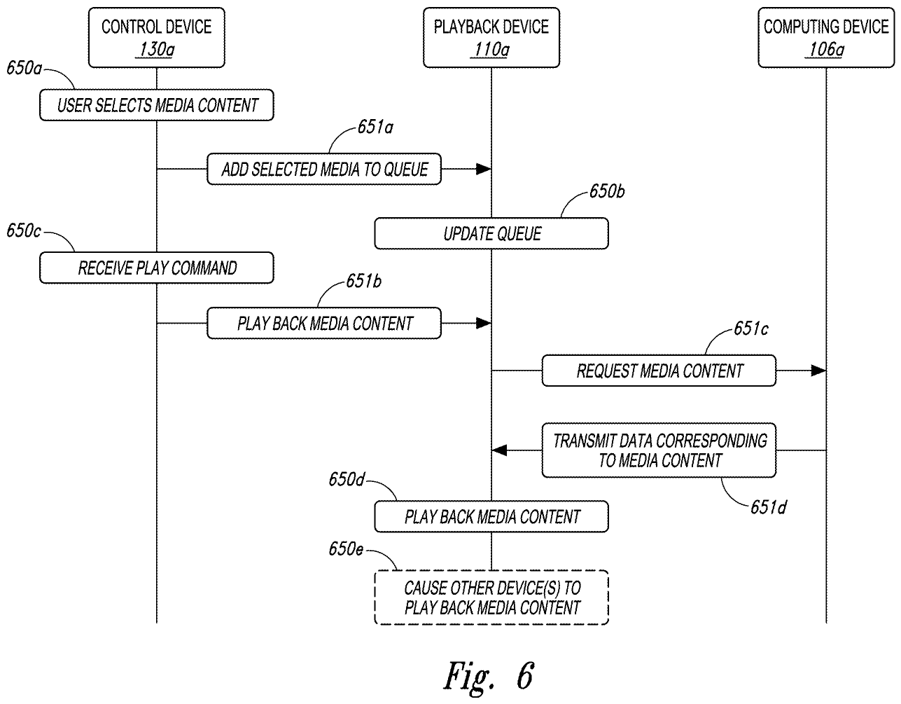

FIG. 6 is a message flow diagram illustrating data exchanges between devices of the media playback system 100 (FIGS. 1A-1M).

At step 650a, the media playback system 100 receives an indication of selected media content (e.g., one or more songs, albums, playlists, podcasts, videos, stations) via the control device 130a. The selected media content can comprise, for example, media items stored locally on or more devices (e.g., the audio source 105 of FIG. 1C) connected to the media playback system and/or media items stored on one or more media service servers (one or more of the remote computing devices 106 of FIG. 1B). In response to receiving the indication of the selected media content, the control device 130a transmits a message 651a to the playback device 110a (FIGS. 1A-1C) to add the selected media content to a playback queue on the playback device 110a.

At step 650b, the playback device 110a receives the message 651a and adds the selected media content to the playback queue for play back.

At step 650c, the control device 130a receives input corresponding to a command to play back the selected media content. In response to receiving the input corresponding to the command to play back the selected media content, the control device 130a transmits a message 651b to the playback device 110a causing the playback device 110a to play back the selected media content. In response to receiving the message 651b, the playback device 110a transmits a message 651c to the first computing device 106a requesting the selected media content. The first computing device 106a, in response to receiving the message 651c, transmits a message 651d comprising data (e.g., audio data, video data, a URL, a URI) corresponding to the requested media content.

At step 650d, the playback device 110a receives the message 651d with the data corresponding to the requested media content and plays back the associated media content.

At step 650e, the playback device 110a optionally causes one or more other devices to play back the selected media content. In one example, the playback device 110a is one of a bonded zone of two or more players (FIG. 1M). The playback device 110a can receive the selected media content and transmit all or a portion of the media content to other devices in the bonded zone. In another example, the playback device 110a is a coordinator of a group and is configured to transmit and receive timing information from one or more other devices in the group. The other one or more devices in the group can receive the selected media content from the first computing device 106a, and begin playback of the selected media content in response to a message from the playback device 110a such that all of the devices in the group play back the selected media content in synchrony.

### VI. Example Embodiments

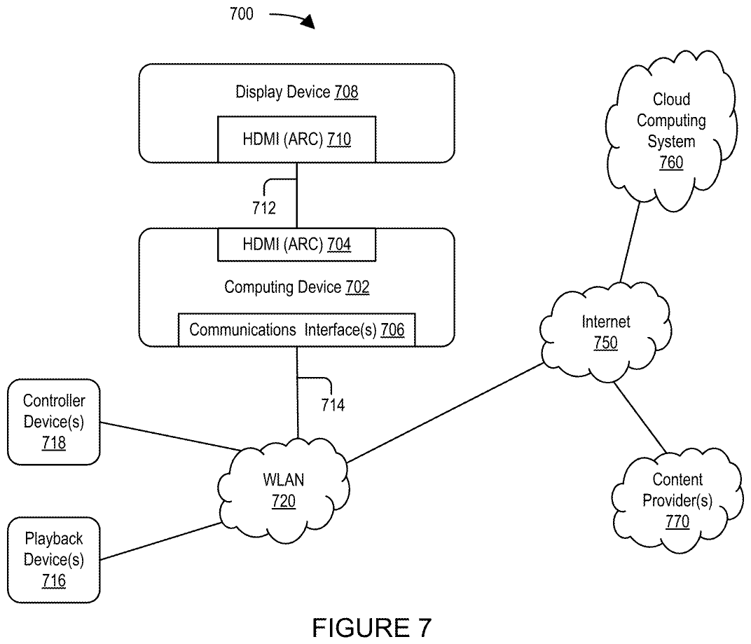

FIG. 7 shows an example system 700 configured to perform dialog (or speech) enhancement based on metadata associated with audio content (sometimes referred to herein as audio content metadata) according to some embodiments. System 700 in FIG. 7 includes a computing device 702 and a cloud computing system 760.

In some embodiments, the computing device 702 comprises a playback device and/or a networked microphone device that is similar to or the same as any of the playback devices and/or networked microphone devices disclosed and described herein. In some embodiments, the computing device 702 is or comprises a soundbar or similar type of playback device comprising one or more home theater center channel speakers. In some embodiments, the computing device 702 comprises a set-top box, a streaming media receiver (such as a Sonos TV terminal, Apple TV terminal, Amazon Fire receiver, Roku receiver, or other type of streaming media terminal or receiver), or any other type of computing device now known or later developed with sufficient network interfaces and processing power to perform any one or more of the features and functions disclosed and described herein.

In some embodiments, the computing device 702 includes one or more network and/or communications interfaces 706, one or more processors (not shown), and tangible, non-transitory computer readable media (not shown) comprising program instructions that, when executed by the one or more processors, cause the computing device 702 to perform any one or more of the features or functions disclosed and described herein. In embodiments where the computing device 702 is or comprises a home theater soundbar or other type of playback device, computing device 702 may also include one or more speakers (not shown). Although system 700 shows computing device 702 and display device 708 as separate components connected via link 712, in some embodiments, computing device 702 and display device 708 may be combined into a single device, e.g., a smart television that includes display functionality and sufficient networking and computing capabilities to perform any one or more of the functions described herein.

The example computing device 702 in system 700 includes (i) one or more communications interfaces 706 and (i) one or more High-Definition Multimedia Interface (HDMI) Audio Return Channel (ARC) interfaces 704.

The one or more communications interfaces 706 may comprise one or more FireWire, USB-C, Thunderbolt, WiFi, Ethernet, Bluetooth, or any other type of wired or wireless interface(s) now known or later developed that are sufficient for transmitting and receiving data, including but not limited to audio content and/or audio content metadata.

The one or more communications interfaces 706 connect the computing device 702 to a wireless local area network (WLAN) 720 via link 714. Link 714 may be any type of wired or wireless communications link now known or later developed that is sufficient for connecting a computing device to a WLAN and facilitating the transmission and receipt of data (i) between the computing device 702 and the WLAN 720 and/or (ii) between and among the computing device 702 and other devices via the WLAN 720 and other computing and information systems via the Internet 750.

For example, in some embodiments, the computing device 702 transmits and/or receives audio content, control information, and/or audio content metadata to and/or from other computing devices via the WLAN 720, such as other playback devices 716, controller devices 718, display devices 708, and other computing devices now known or later developed. Further, in some embodiments, the computing device 702 and the cloud computing system 760 exchange data each other and with content providers 770 via the Internet 750.

The HDMI ARC interface 704 of computing device 702 is connected via link 712 to a corresponding HDMI ARC interface 710 of display device 708. The display device 708 may be a television or any other type of device configured to display video data, e.g., a monitor, projector, or similar display device. In operation, link 712 may be a physical HDMI link or a wireless HDMI link. In some embodiments, interface 704 on the computing device 702 and interface 710 on the display device 708 (and corresponding link 712) may operate according to a wired or wireless protocol other than HDMI, such as FireWire, USB-C, Thunderbolt, WiFi, Ethernet, Bluetooth, or any other protocol now known or later developed that is suitable for transmitting audio content and/or metadata associated with audio content.

As mentioned above, computing device 702, individually or in combination with one or more other computing devices and/or systems (e.g., controller device(s) 718, playback device(s) 716, cloud computing system 760, and/or content provider(s) 770) is configured to perform dialog enhancement features based on audio content metadata. To determine which portions of audio content comprise dialog, some embodiments disclosed herein include analyzing the audio content metadata to determine when dialog is present in a portion of the audio content. In some embodiments, the audio content metadata includes closed caption data associated with the audio content, or perhaps other forms of data that include indications of spoken dialog that are time-aligned to the audio content. Closed caption data that is time-aligned with the audio content allows the text of the dialog to be displayed onscreen at the same time (or at substantially the same time) as the audio of the dialog is played during playback of the content.

In contrast to some existing systems where playback device operates either in a “dialog enhancement mode” or not in the “dialog enhancement mode” based on whether audio content includes dialog, embodiments disclosed herein selectively (i) apply dialog enhancement parameters to individual portions of the audio content containing dialog and (ii) does not apply the dialog enhancement parameters to portions of the audio content where dialog is not present.

In this way, the systems disclosed and described herein perform active dialog enhancement in a way that seeks to apply (or engage) the dialog enhancement parameters preferably just during the portions of audio content comprising at least some dialog, but not apply (or disengage) the dialog enhancement parameters during portions of the audio content that do not contain at least some dialog.

Rather than engaging and disengaging a set of dialog enhancement parameters to audio content in a binary on/off fashion, some embodiments may implement changes to the audio processing in a more subtle way depending on the type or source of the audio content and/or an analysis of the audio content. For example, some embodiments may “phase in” dialog enhancement over 1-5 seconds before dialog is to be played, and then “phase out” dialog enhancement over 1-5 second after dialog has been played, thereby making the transition from playing audio with and without dialog enhancement less noticeable to listeners.

In another example, some embodiments may additionally or alternatively engage and disengage one or more subsets of dialog enhancement parameters in a larger set of dialog enhancement parameters to the audio content based on factors such as (i) the type of audio content (e.g., applying more dialog enhancement parameters for a movie or fewer dialog enhancement parameters for a podcast on the assumption that the dialog in a loud movie will be more difficult to discern from the rest of the audio content in the movie as compared to a podcast where the dialog may be easier to discern from the rest of the audio content in the podcast), (ii) a genre (e.g., applying more dialog enhancement parameters for an action movie and fewer dialog enhancement parameters for a documentary on the assumption that the dialog in an action movie will be more difficult to discern from the rest of the audio content in the movie as compared to a documentary where the dialog may be easier to discern from the rest of the audio content in the documentary), (iii) a likelihood that the audio content includes dialog (e.g., applying more dialog enhancement parameters to audio content having a higher likelihood of containing dialog or applying fewer dialog enhancement parameters to audio content having a lower likelihood of containing dialog), or (iv) a loudness or spectral density of the audio content (e.g. applying more dialog enhancement parameters to audio content that is louder and/or has a higher spectral density or applying fewer dialog enhancement parameters to audio content that is quieter and/or has a lower spectral density on the assumption that dialog contained in louder and/or higher spectral density portions of the audio content may be more difficult to discern as compared to dialog contained in software and/or lower spectral density portions of the audio content).

In yet another example, some embodiments may additionally or alternatively mix a version of the unaltered audio content with a version of the dialog enhanced audio content based on factors such as (i) the type of audio content (e.g., playing a mix with more dialog enhanced audio content than unaltered audio content for a loud movie or a mix with less dialog enhanced audio content than unaltered audio content for a podcast on the assumption that the dialog in a loud movie will be more difficult to discern from the rest of the audio content in the movie as compared to a podcast where the dialog may be easier to discern from the rest of the audio content in the podcast), (ii) a genre (e.g., playing a mix with more dialog enhanced audio content than unaltered audio content for an action movie or a mix with less dialog enhanced audio content than unaltered audio content for a documentary on the assumption that the dialog in an action movie will be more difficult to discern from the rest of the audio content in the movie as compared to a documentary where the dialog may be easier to discern from the rest of the audio content in the documentary), (iii) a likelihood that the audio content includes dialog (e.g., playing a mix with more dialog enhanced audio content than unaltered audio content for audio content that is more likely to include dialog or a mix with less dialog enhanced audio content than unaltered audio content for audio content that is less likely to include dialog), or (iv) a loudness or spectral density of the audio content (e.g. playing a mix with more dialog enhanced audio content than unaltered audio content for louder and/or more spectrally dense audio content or a mix with less dialog enhanced audio content than unaltered audio content for quieter and/or less spectrally dense audio content on the assumption that dialog contained in louder and/or higher spectral density portions of the audio content may be more difficult to discern as compared to dialog contained in software and/or lower spectral density portions of the audio content). Still further embodiments may include any combination of one or more of the above-described approaches of (i) phasing in and out dialog enhancement, (ii) activating different subsets of dialog enhancement parameters in different contexts, and/or (iii) mixing dialog-enhanced audio with the original audio in different amounts in different contexts.

However, in operation, because some audio content metadata may include indications of spoken dialog during portions of the audio content that may not actually include spoken dialog, it is possible in some situations for some embodiments to apply (or engage) the dialog enhancement parameters during portions of audio content that may not actually include spoken dialog. Accordingly, some embodiments described further herein include additionally (i) for portions of audio content indicated by the audio content metadata as including dialog, analyzing those portions of audio content to determine whether the audio analysis also indicates that those portions include dialog, and (ii) apply dialog enhancement parameters to the portions that of audio content indicated as including dialog based on both the audio content metadata and the audio analysis.

As mentioned above, computing device 702, individually or in combination with one or more other computing devices and/or systems (e.g., controller device(s) 718, playback device(s) 716, cloud computing system 760, and/or content provider(s) 770) is configured to perform dialog enhancement based on audio content metadata.

Some embodiments include the computing device 702 receiving and analyzing the audio content metadata (e.g., closed caption or similar data) to determine which portions of the audio content include dialog. In such embodiments, the computing device 702 (i) determines portions of the audio content that include dialog based at least in part on the audio content metadata, and (ii) for individual portions of the audio content that the computing device 702 has determined to include dialog, identify one or more dialog enhancement parameters for application to the individual portions of the audio content that the computing device 702 has determined to include dialog (based on the audio content metadata). Identifying the one or more dialog enhancement parameters may include, e.g., accessing the dialog enhancement parameters stored in local memory, looking up the dialog enhancement parameters in a local or remote database, receiving the dialog enhancement parameters via a stream of control information or via a datafile, or any other method of identification.

Some embodiments additionally include the computing device 702 playing the audio content, and while playing the audio content, applying the one or more dialog enhancement parameters to the individual portions of the audio content that the computing device 702 has determined to include dialog based on the audio content metadata. Some embodiments alternatively include the computing device 702 using the one or more dialog enhancement parameters to modify the audio content, temporarily buffering at least a portion of modified audio content, and then playing the modified audio content.

Other embodiments include the cloud computing system 760 receiving and analyzing the audio content metadata (e.g., closed caption or similar data) to determine which portions of the audio content include dialog. In such embodiments, the cloud computing system (i) determines portions of the audio content that include dialog based at least in part on the audio content metadata, and (ii) for individual portions of the audio content that the cloud computing system 760 has determined to include dialog, identify one or more dialog enhancement parameters for application to the individual portions of the audio content that the cloud computing system 760 has determined to include dialog. As described above, identifying the one or more dialog enhancement parameters may include, e.g., accessing the dialog enhancement parameters stored in local memory, looking up the dialog enhancement parameters in a local or remote database, receiving the dialog enhancement parameters via a stream of control information or via a datafile, or any other method of identification.

Some embodiments additionally include the cloud computing system 760 causing one or more playback devices (e.g., computing device 702 and/or playback device(s) 716) to play the audio content with the one or more dialog enhancement parameters applied to at least the individual portions of the audio content that the cloud computing system 760 has determined to include dialog.

For embodiments where the computing device 702 receives and analyzes the audio content metadata to determine which portions of the audio content include dialog, the computing device 702 may receive the audio content metadata from any of a variety of sources. For example, in some embodiments, the computing device 702 receives the audio content metadata from the display device 708 via link 712 between the HDMI ARC interface 710 on the display device 708 and the HDMI ARC interface 704 on the computing device 702. In other embodiments, the computing device 702 receives the audio content metadata from any of the controller device 718, another playback device 716, the content provider 770, or the cloud computing system 760.

In operation, the computing device 702 can be configured to receive data comprising any of the audio content and/or audio content metadata from any of the sources and/or via any of the mechanisms or other network configurations disclosed and described in U.S. Prov. 63/224,491, titled “Wireless Streaming of Audio/Visual Content in a Home Theater Architecture,” filed on Jul. 22, 2021, which is currently pending, and which is assigned to Sonos, Inc. The entire contents of U.S. Prov. 63/224,491 are incorporated herein by reference.

Similarly, for embodiments where the cloud computing system 760 performs the functions of receiving and analyzing the audio content metadata to determine which portions of the audio content include dialog, the cloud computing system 760 may receive the audio content metadata from any of a variety of sources. For example, in some embodiments, the cloud computing system 760 receives the audio content metadata from the computing device 702, which can obtain the audio content metadata from any of several sources (e.g., the display device 708, controller device 718, other playback devices 716, or the content provider 770) before the computing device 702 forwards the audio content metadata to the cloud computing system 760. In other embodiments, the cloud computing system 760 receives the audio content metadata from any of the controller device 718, the display device 708, the other playback device 716, or from the content provider 770 directly.

Regardless of the source of the audio content metadata, the computing device 702 or the cloud computing system 760 may receive the audio content metadata via either (i) a stream comprising the audio content metadata or (ii) a file comprising the audio content metadata.

In some embodiments where the audio content metadata is received via a stream comprising the audio content metadata, the stream comprising the audio content metadata is or comprises a data stream that is separate from a stream comprising the audio content. In other embodiments, the stream comprising the audio content metadata is the same stream that comprises the audio content, i.e., the computing device 702 or the cloud computing system 760 receives a stream comprising the audio content and the audio content metadata.

In some embodiments where the audio content metadata is received in a file, the file is or comprises a data file that is separate from a stream or data file comprising the audio content. In other embodiments, the file comprising the audio content metadata is the same file that comprises the audio content, i.e., the computing device 702 receives a file comprising the audio content and the audio content metadata.

In some embodiments, the dialog enhancement parameters that the computing device 702 applies to the portions of the audio content that include dialog comprises at least one or more of equalization settings, surround sound settings, and/or volume settings configured to enhance dialog contained with audio content.

For example, in some embodiments, the dialog enhancement parameters comprise one or more amplitudes of one or more frequency ranges of the audio content. In such embodiments, applying the dialog enhancement parameters include adjusting (relative to a then-existing level) one or more amplitudes of one or more frequency ranges of the audio content during playback of the portions of the audio content determined to comprise speech. Thus, in operation, applying the dialog enhancement parameters in some embodiments includes increasing (relative to a then-existing level) an amplitude of the audio content within a first frequency range during playback of the at least one portion of the audio content determined to comprise dialog. Increasing the amplitude of the audio content within the first frequency range in this manner in some embodiments includes amplifying content in a frequency range that tends to include dialog, e.g., between about 300 Hz to about 3400 Hz. In some embodiments that additionally include analyzing the audio content, the first frequency range may include a frequency range based on the audio content analysis. For example, if the audio content analysis shows audio energy within a range of between about 1000 Hz to 2500 Hz, then applying the dialog enhancement parameters may include amplifying the audio content within a frequency range of between about 1000 Hz and about 2500 Hz. But for embodiments that may not include separately analyzing the audio content, a more generalized range (e.g., between about 300 Hz to about 3400 Hz) may be used.

In operation, applying the dialog enhancement parameters in some embodiments may additionally or alternatively include decreasing (relative to a then-existing level) the amplitude of the audio content within one or more second frequency ranges different than the first frequency range during playback of the at least one portion of the audio content determined to comprise dialog. Decreasing the amplitude of the audio content within the one or more second frequency ranges in this manner in some embodiments includes attenuating (relative to a then-existing level) content in a frequency range below about 300 Hz and/or attenuating content in a frequency range above about 3400 Hz. In some embodiments that additionally include analyzing the audio content, the one or more second frequency ranges may include one or more frequency ranges based on the audio content analysis. For example, if the audio content analysis shows audio energy within a range of between about 1000 Hz to 2500 Hz, then applying the dialog enhancement parameters may include attenuating the audio content below about 1000 Hz and/or attenuating the audio content above about 2500 Hz. But for embodiments that may not include separately analyzing the audio content, a more generalize range (e.g., below about 300 Hz and/or above 3400 Hz) may be used.

In some embodiments, applying the dialog enhancement parameters to the audio content to amplify audio content within a certain frequency range and/or attenuate audio content within other frequency ranges includes applying one or more filters to the audio content to attenuate audio content within frequencies outside of the frequency range comprising the dialog.

In some embodiments, the dialog enhancement parameters may additionally or alternatively comprise one or more surround sound settings. In such embodiments, applying the dialog enhancement parameters include adjusting (relative to then-existing settings) the surround sound settings during playback of the portions of the audio content determined to include dialog. Thus, in operation, applying the dialog enhancement parameters in some embodiments additionally or alternatively includes changing the surround sound parameters during playback of the at least one portion of the audio content determined to comprise dialog.

Changing the surround sound parameters in this manner in some embodiments may include any one or more of, (i) increasing the volume of one or more center channel speaker(s) (e.g., speakers at computing device 702), (ii) reducing the volume of one or more satellite speakers (e.g., speakers at playback device(s) 716), (iii) changing one or more surround sound delay settings to narrow the sound field projected by the center channel speakers, thereby making it easier for a listener focus on the dialog, (iv) changing the directionality of the sound projected by the center channel speakers to focus the sound in a narrow region in front of the computing device 702, and/or (v) mixing some of the center channel information (the channel most likely to contain dialog, or perhaps another channel that includes dialog) into one or more of the satellite channels (e.g., rear left, rear right, overhead, etc.) so as to cause additional speakers to play the dialog.

In operation, changing the surround sound parameters during playback may be accomplished in several different ways. For example, in some embodiments, the cloud computing system 760 (or perhaps controller device 718) may send commands to the computing device 702 and/or the satellite playback devices (e.g., playback devices 716) that, when implemented by the computing device 702 and/or the satellite playback devices (e.g., playback devices 716), cause the computing device 702 and/or the satellite playback devices (e.g., playback devices 716) to change one or more of their surround sound parameters during playback of the audio content. Additionally or alternatively, the cloud computing system 760 (or perhaps controller device 718) may apply one or more changed surround parameters to the audio content, and then send the modified audio content to the computing device 702 and/or the satellite playback devices (e.g., playback devices 716) for playback.

In other embodiments, the playback device 702 may send commands to the satellite playback devices (e.g., playback devices 716) that, when implemented by the satellite playback devices, cause the satellite playback devices to change one or more of their surround sound parameters during playback of the audio content. Additionally or alternatively, the computing device 702 may apply one or more changed surround parameters to the audio content, and then send the modified audio content to the satellite playback devices (e.g., playback devices 716) for playback.

Some embodiments may additionally or alternatively include activating an auxiliary playback device (e.g., one of the playback device(s) 716), an auxiliary speaker associated with a playback device (e.g., a speaker associated with or otherwise connected to computing device 702 or one of the playback device(s) 716), and/or headphones or earphone(s) to play dialog. For example, in some embodiments applying the dialog enhancement parameters to the audio content may additionally or alternatively include (i) processing the audio content to extract dialog, amplify dialog, and/or attenuate content other than dialog to generate dialog-enhanced audio, and/or (ii) playing the dialog-enhanced audio via the auxiliary playback device and/or speaker. In some embodiments, the auxiliary playback device may include a playback device that is (i) positioned in a listening area close to where listeners typically listen to audio content in the listening area and/or (ii) configured to emphasize playback of dialog. In embodiments comprising an auxiliary speaker associated with a playback device, the auxiliary speaker may similarly be (i) positioned in the listening area close to where listeners typically listen to audio content in the listening area, and/or (ii) configured to emphasize playback of dialog. In further embodiments comprising an auxiliary speaker associated with a playback device, the auxiliary speaker may be integrated into a playback device (e.g., computing device 702 or another playback device 716) and configured to emphasize playback of dialog. For example, a soundbar device may include one or more specific speakers that are configured to emphasize dialog and/or play the dialog-enhanced audio.

Some embodiments additionally include using audio analysis (e.g., speech detection and/or recognition algorithms) to further fine tune the activation and deactivation of the dialog enhancement parameters during playback of the audio content in order to more accurately apply the dialog enhancement parameters to portions of the audio content containing dialog while also refraining from applying the dialog enhancement parameters to the portions of the audio that do not contain dialog. Some embodiments alternatively include using audio analysis (e.g., speech detection and/or recognition algorithms) to identify portions of audio content containing dialog in the first instance, i.e., using audio analysis rather than metadata to identify portions of audio content containing dialog. Embodiments that are configured to use audio analysis to identify portions of audio content containing dialog are advantageous in several situations, including but not limited to situations where metadata (e.g., closed caption data that is time-aligned to the audio content) may not exist, may not be available, and/or may not be suitable for analysis to determine portions of audio content containing dialog.

Some embodiments that additionally use speech detection and/or recognition algorithms additionally include (i) determining that a portion of the audio content comprises dialog based audio content metadata (e.g., closed caption data that is time-aligned to the audio content), and (ii) applying a speech detection and/or recognition algorithm the portion of the audio content determined to comprise the dialog to identify one or more sub-portions of the audio content where the dialog is present. In operation, a sub-portion of audio content where the dialog is present has a shorter duration than the duration of the portion of audio content determined to comprise dialog based on the audio content metadata.

For example, the audio content metadata may include closed captioning data indicating that dialog is present within one 10-second portion of the audio content starting at 3 minutes and 10 seconds (3:10) into playback of the audio content and ending at 3 minutes and 20 seconds (3:20) into playback of the audio content. However, the dialog may not be spoken for that full 10 second portion of the audio content. Instead, a first character may say, “Hi, how are you?” from 3:10 to 3:12, and a second character may respond, “I'm fine, and you?” from 3:15 to 3:17. Although the closed caption data includes instructions to display the dialog between the two characters for the full 10 seconds from 3:10 to 3:20 (the portion of audio data comprising dialog), the audio content includes spoken dialog only for 4 seconds out of the total 10 seconds of that portion of the audio content, where the four seconds includes a first sub-portion (from 3:10 to 3:12) and a second sub-portion (from 3:15 to 3:17).

By additionally using one or more speech detection and/or recognition algorithms to determine sub-portions (e.g., the two 2-second sub-portions) of the audio content containing dialog that are more precise than the larger portion (e.g., the full 10-second portion) of the audio content, some embodiments are able to more accurately apply the dialog enhancement parameters to smaller sub-portions of the audio content (and not apply the dialog enhancement parameters where unnecessary) as compared to embodiments that may not additionally use speech detection and/or recognition algorithms.

In some embodiments, using one or more speech detection and/or recognition algorithms to determine sub-portions of the audio content that are more precise than the larger portion of the audio content enables the dialog enhancement parameters to be gradually activated and deactivated in a “smooth” fashion so as to make the transition from playing audio content without dialog enhancement to playing audio content with dialog enhancement (and vice versa) less noticeable to the listener. For example, some embodiments are configured to “phase in” the dialog enhancement parameters over 1-5 seconds in advance of playing dialog, and then “phase out” the dialog enhancement parameters over 1-5 seconds after playing dialog to make the activating and deactivating less noticeable to the listener.

However, embodiments that may not incorporate speech detection and/or recognition algorithms can also benefit from the gradual activation and deactivation of dialog enhancement parameters, too. For example, such embodiments can still be configured to “phase in” the dialog enhancement parameters over 1-5 seconds in advance of playing dialog, and then “phase out” the dialog enhancement parameters over 1-5 seconds after playing dialog to make the activating and deactivating less noticeable to the listener. But such embodiments may not benefit from the ability to more finely tune the gradual activation and deactivation of the dialog enhancement parameters in the same way as embodiments that use one or more speech detection and/or recognition algorithms to determine sub-portions of the audio content that are more precise than the larger portion of the audio content.

So, for a 10 second portion of audio content that may only contain 4 second of actual dialog, some embodiments may gradually phase in the dialog enhancement parameters over 1-5 seconds before the start of the 10 second portion, keep the dialog enhancement parameters active during the full duration of the 10 second portion (i.e., for 10 seconds), and then gradually phase out the dialog enhancement parameters over 1-5 second after the conclusion of the 10 second portion, thereby playing the audio content with some amount of dialog enhancement for 12-20 seconds. By comparison, embodiments that additionally use speech detection and/or recognition to identify sub-portions of the audio content that are more precise than the larger portion as described above may play the audio content with some amount of dialog enhancement for a shorter duration, depending on the duration of the sub-portion(s) relative to the duration of the larger portion.

Additionally, using the audio content metadata to identify portions of audio content containing dialog enables targeted application of the speech detection and/or recognition algorithms because the speech detection and/or recognition algorithms can be applied just to those portions of the audio content that include dialog—the speech detection and/or recognition algorithms need not be applied to all of the audio content. This targeted application of the speech detection and/or recognition algorithms speeds up the speech detection and/or recognition process by reducing the amount of audio content to be analyzed by the speech detection and/or recognition algorithm(s). In addition, by applying the dialog enhancement parameters to just the sub-portions of a portion of audio content containing the dialog rather than the entire portion of audio content containing the dialog, listeners receive the benefit of the dialog enhancement for the sub-portions that include dialog while not affecting the sub-portions that do not include any dialog.

In some embodiments, the use of speech detection and/or recognition in combination with the audio content metadata to the fine tune the selective application of the dialog enhancement parameters to the audio content can performed by the computing device 702 or by the cloud computing system 760, either individually or in cooperation with each other.

For example, when streaming video content from a content provider 770, the computing device 702 may, individually or in cooperation with the display device 708 (or perhaps another computing device connected to and/or associated with the computing device 702 and/or display device 708, such as a set-top box or similar), buffer a few seconds to perhaps a few minutes of video and/or audio content. In operation, the computing device 702 can identify portions of the buffered audio content containing dialog by referring to the audio content metadata (e.g., time-aligned closed caption data). And then for the portions of the buffered audio content that include dialog, the computing device 702 can apply the one or more speech detection and/or recognition algorithms to those portions to pick out the specific sub-portions that include the dialog. Then, the computing device 702 can selectively apply the dialog enhancement parameters to those identified sub-portions of the audio content during playback.

In another example, the cloud computing system 760 may stream video content from a content provider 770 (or perhaps just the audio content associated with the video content from the content provider 770) and buffer a few seconds to perhaps a few minutes of video and/or audio content. In operation, the cloud computing system 760 can identify portions of the buffered audio content containing dialog by referring to the audio content metadata (e.g., time-aligned closed caption data). And then for the portions of the buffered audio content that include dialog, the cloud computing system 760 can apply the one or more speech detection and/or recognition algorithms to those portions to pick out the specific sub-portions that include the dialog. Then, the cloud computing system 760 can selectively apply the dialog enhancement parameters to those identified sub-portions of the audio content to (i) create modified audio content and/or (ii) cause a playback device to play the modified audio content. In some embodiments, the cloud computing system 760 may generate and stream the modified audio content (i.e., the audio content with the dialog enhancement parameters applied thereto) to the computing device 702 for playback. In other embodiment, the cloud computing system 760 may generate a set of dialog enhancement playback parameter application instructions that are time-aligned to the audio content that, when executed by the computing device 702, cause the computing device 702 to apply the dialog enhancement parameters to the appropriate portions (and/or sub-portions) of the audio content during playback.

In another example, the cloud computing system 760 may perform the above-described processing “off line” for a movie or television show to generate a set of dialog enhancement playback parameter instructions that are specific to the audio content for that particular movie or television show. For example, the cloud computing system 760 may use closed caption data to identify portions of the movie Star Wars that include dialog. Then, the cloud computing system 760 can apply one or more speech detection and/or recognition algorithms to those portions containing dialog to identify the sub-portions thereof that include the dialog. Then, the cloud computing system 760 can generate a set of playback instructions that are specific to the audio content for the Star Wars movie. Then, when the display device 708 and/or computing device 702 streams Star Wars from content provider 770, the display device 708 and/or computing device 702 additionally requests the playback instruction file for Star Wars from the cloud computing system 760. In operation, the playback instruction file for the Star Wars movie includes time-aligned commands (or instructions) to apply the one or more dialog enhancement parameters to particular portions (or perhaps sub-portions) of the audio for the Star Wars movie so that listeners are better able to hear and understand the dialog spoken by the characters while not detracting from the explosions, crashes, laser fire, and other loud noises that make the Star Wars movie enjoyable to watch on a home theater system.

In some embodiments, once the computing device 702 and/or cloud computing system 760, individually or in combination have determined a set of time-aligned commands (or instructions) to apply the one or more dialog enhancement parameters to particular portions (or perhaps sub-portions) of the audio for a specific movie or television show, that set of time-aligned commands (or instructions) can be stored (e.g., at the cloud computing system 760 or some other cloud storage location) and associated with that specific movie or television show. Once that set of time-aligned commands (or instructions) has been stored and associated with that specific movie or television show, then when another user streams that specific movie or television show, that user's home theater system can play the audio content associated with that movie or television show according to that set of time-aligned dialog enhancement commands.

In some embodiments, the cloud computing system 760 may additionally or alternatively use the set of time-aligned dialog enhancement commands to generate a “dialog enhanced” version of the audio content that the cloud computing system 760 can stream to any home theater system that requests the “dialog enhanced” version of the audio content. In other embodiments, the cloud computing system 760 can send the time-aligned dialog enhancement commands associated with that specific movie or television show to a home theater system, and the playback devices in that home theater system can implement the time-aligned dialog enhancement commands locally during playback of the audio content associated with that specific movie or television show.

Additionally or alternatively, some embodiments may include the computing device 702 and/or cloud computing system 760 using one or more speech detection and/or recognition algorithms to confirm that a particular portion of audio content includes dialog in connection with determining whether to apply the dialog enhancement parameters to that particular portion of audio content. For example, after determining that the audio content metadata indicates that a particular portion of audio content includes dialog, some embodiments include applying the one or more speech detection and/or recognition algorithms to that particular portion of audio content to confirm whether that particular portion of audio content includes dialog, e.g., to check whether the speech detection and/or recognition algorithm result is consistent with the information indicated in the audio content metadata. In such embodiments, applying the dialog enhancement parameters to the audio content may include applying the dialog enhancement parameters to a portion of the audio content only if that portion of audio content is determined to contain dialog based on both (i) the audio content metadata and (ii) the results of applying the speech detection and/or recognition algorithm(s) to that portion of audio content.

Other embodiments may alternatively include applying one or more speech detection and/or recognition algorithms to the audio content to identify portions of audio content comprising dialog, and then using the audio content metadata to confirm the results of the speech detection and/or recognition algorithm(s).

In addition to using the audio content metadata and/or speech detection and/or recognition algorithms to identify portions of the audio content that include dialog, some embodiments also include analyzing the substance and/or character of the dialog, and applying one or more dialog enhancement parameters based on the substance and/or character of the dialog. For example, the dialog enhancement playback parameter(s) applied to whispered dialog in some embodiments may be different than the dialog enhancement playback parameter(s) applied to shouted dialog. Whether certain dialog is whispered or shouted may be indicted by the audio content metadata (e.g., indicating a whisper or yell) or via the speech detection and/or recognition algorithm(s) (e.g., determining the volume or spectral components of the dialog to determine whether the dialog is whispered, yelled, or spoken in an ordinary manner). In another example, the dialog enhancement playback parameter(s) applied to dialog spoken in a deep voice in some embodiments may be different than the dialog enhancement playback parameter(s) applied to dialog spoken in a higher-pitched voice. For example, the dialog enhancement playback parameter(s) may include amplifying frequencies at the lower end of the 300-3400 Hz human voice range for dialog spoken in a deep voice but amplifying frequencies at the higher end of the 300-3400 Hz human voice range for dialog spoken in a higher-pitched voice. Whether certain dialog is spoken in a deep vs. high-pitched voice may be indicted by the audio content metadata or via the speech detection and/or recognition algorithm(s) (e.g., determining the volume or spectral components of the dialog to determine whether the dialog is spoken in a deep voice, typical voice, or high-pitched voice).

In addition to using the audio content metadata to identify portions of the audio content that include dialog, some embodiments also use the audio content metadata to identify portions of the audio content that do not include dialog. For example, sometimes the closed caption data may include no dialog for portions of the audio content. This may happen, for example, during portions of a movie or television show where no speaking characters appear in a scene, or when the characters in a scene simply are not talking. Some embodiments use this indication of a lack of dialog during certain portions of a movie to further improve a listener's experience.

For example, in the same way that the computing device 702 and/or cloud computing system 760, individually or in combination, use indications of dialog contained within the audio content metadata to selectively apply one or more dialog enhancement parameters to particular portions of the audio content as described above, the computing device 702 and/or cloud computing system 760, individually or in combination, in some embodiments is additionally or alternatively configured to (i) determine a portion of the audio content lacking dialog based at least in part on the audio content metadata, and (ii) for a portion of the audio content determined to lack dialog, (a) identify at least one playback parameter for application to that portion of the audio content lacking dialog, and (ii) apply the identified at least playback parameter to that portion of the audio content during playback of the audio content.

Like the dialog enhancement parameters described above, the “no dialog” playback parameters may include one or more amplitudes of one or more frequency ranges such that applying one or more “no dialog” playback parameters to audio content includes adjusting one or more amplitudes of one or more frequency ranges of the audio content during playback of a portion of the audio content determined to lack dialog as indicated by the audio content metadata. For example, if audio content metadata indicates that a portion of the audio content (e.g., a 93 second car chase scene) lacks spoken dialog, then the computing device 702 may apply one or more “no dialog” playback parameters to the audio content during that portion of the audio content that contains no dialog, as indicated by the audio content meta.

In some embodiments, the one or more “no dialog” playback parameters may correspond to a regular, baseline, or default set of playback parameters that would be applied to the audio content in the ordinary course of playback. In this manner, applying the “dialog enhancement” playback parameters includes changing (from the then-active) playback parameters when playing the dialog, and applying the “no dialog” playback parameters includes returning to the previously-active playback parameters. Thus, in operation, during playback of the audio content, playback switches back-and-forth between (i) playing the portions of the audio content containing dialog according to the “dialog enhancement” playback parameters and (ii) playing the portions the audio content lacking dialog according to the “no dialog” playback parameters.

In operation, the computing device 702 and/or cloud computing system 760, individually or in combination, may determine a portion of the audio content lacking dialog based at least in part on the audio content metadata, identify one or more “no dialog” playback parameters for application to that portion of the audio content lacking dialog, and apply the identified one or more “no dialog” playback parameters to that portion of the audio content during playback of the audio content in the same manner as any of the ways disclosed and described above that the computing device 702 and/or cloud computing system 760, individually or in combination, determines a portion of the audio content comprising dialog based at least in part on the audio content metadata, identifies one or more dialog enhancement parameters for application to that portion of the audio content comprising dialog, and applies the identified one or more dialog enhancement parameters to that portion of the audio content during playback of the audio content.

In addition to using the audio content metadata to identify portions of the audio content that include dialog and/or lack dialog, some embodiments also use the audio content metadata to identify portions of the audio content that include scene-specific audio. For example, sometimes closed caption data may include information about a scene, such as “jazz music playing,” “crowd cheering,” “tires screeching,” or “loud explosion.” Often, these types of scene-specific audio indications are set off with brackets, parentheses, and/or italics. Some embodiments use these types of indications of scene-specific audio to further improve a listener's experience.

For example, in the same way that the computing device 702 and/or cloud computing system 760, individually or in combination, uses indications of dialog contained within the audio content metadata to selectively apply one or more dialog enhancement parameters to particular portions of the audio content as described above, the computing device 702 and/or cloud computing system 760, individually or in combination, in some embodiments is additionally or alternatively configured to (i) determine a portion of the audio content comprising scene-specific audio based at least in part on the audio content metadata, and (ii) for a portion of the audio content determined to comprise scene-specific audio, (a) identify one or more scene-specific audio playback parameters for application to that portion of the audio content comprising scene-specific audio, and (ii) apply the identified one or more scene-specific audio playback parameters to that portion of the audio content during playback of the audio content.

Like the dialog enhancement parameters described above, the scene-specific audio playback parameters may include one or more amplitudes of one or more frequency ranges such that applying one or more scene-specific audio playback parameters to audio content includes adjusting one or more amplitudes of one or more frequency ranges of the audio content during playback of a portion of the audio content determined to include scene-specific audio as indicated by the audio content metadata.

For example, if audio content metadata includes information about a scene such as “jazz music playing,” then the computing device 702 and/or cloud computing system 760 may apply one or more scene-specific audio playback parameters associated with jazz music to the audio content during that portion of the audio content that contains the jazz music, as indicated by the audio content meta. In another example, if audio content metadata includes information about a scene such as “crowd cheering,” then the computing device 702 and/or cloud computing system 760 may apply one or more scene-specific audio parameters associated with cheering crowds, such as changing one or more surround sound parameters to enhance the surround sound effect of the cheering crowd. In another example, if audio content metadata includes information about a scene such as “loud explosion,” then the computing device 702 and/or cloud computing system 760 may apply one or more scene-specific audio parameters associated with explosions, such as changing one or more surround sound parameters to enhance the surround sound effect of explosion.

In operation, the computing device 702 and/or cloud computing system 760, individually or in combination, may determine a portion of the audio content comprising scene-specific audio based at least in part on the audio content metadata, identify at least one scene-specific audio playback parameter for application to that portion of the audio content comprising scene-specific audio, and apply the identified at least one scene-specific audio playback parameter to that portion of the audio content during playback of the audio content in the same manner as any of the ways disclosed and described above that the computing device 702 and/or cloud computing system 760, individually or in combination, determines a portion of the audio content comprising dialog based at least in part on the audio content metadata, identifies one or more dialog enhancement parameters for application to that portion of the audio content comprising dialog, and applies the identified one or more dialog enhancement parameters to that portion of the audio content during playback of the audio content.

Sometimes, a listener may not like the result of the dialog enhancement procedures described above. In operation, the computing device 702 and/or the cloud computing system 760, individually or in combination, may infer that the listener dislikes the result of the dialog enhancement being applied to the audio content based on receipt of a playback adjustment command, such as one or more volume change and/equalization adjustment commands.

For example, if while the above-described dialog enhancement procedures are being applied to the portions of the audio content comprising dialog, the listener continues to increase and/or decrease the volume during portions of the audio content with or without dialog, respectively, then the computing device 702 and/or cloud computing system 760 can infer that the dialog enhancement procedures are likely not enhancing the dialog as well as they could for that particular user.

In such a situation, some embodiments include modifying one or more of the dialog enhancement parameters for application to the portions of the audio content comprising dialog. For example, for embodiments that include increasing the amplitude of the audio content within a frequency range that includes dialog and/or decreasing the amplitude of the audio content within one or more frequency ranges above or below the frequency range that includes dialog, modifying the one or more dialog enhancement parameters may include further increasing the amplitude of the audio content within the frequency range including dialog and/or further decreasing the amplitude of the audio content within the frequency ranges above or below the frequency range including dialog. Modifying one or more of the dialog enhancement parameters in this manner will further enhance the dialog and make it easier for the listener to discern from other sounds in the audio content.

In another example, modifying one or more of the dialog enhancement parameters may include adjusting the frequency ranges that are amplified and/or attenuated. For example, if the frequency range including the dialog is between about 300 Hz to about 3400 Hz, then narrowing the range to between about 1000 Hz to about 2000 Hz may allow the listener to better discern the dialog from the other sound in the audio content. Although such a modification may alter or affect the sound of characters' voices to some extent, a listener may prefer that result if it makes the dialog more intelligible.

If, after implementing the modified dialog enhancement playback parameter(s), the listener stops increasing and/or decreasing the volume during portions of the audio content with or without dialog, respectively—or at least reduces the frequency of the increasing and/or decreasing below some threshold frequency—then the computing device 702 and/or cloud computing system 760 can infer that the modified dialog enhancement parameters are likely more preferable for that particular listener than they were previously. For example, if the listener changes the volume up or down fewer than 3 times within a 15 minute period, then the modified dialog enhancement playback parameter(s) are likely more effective at enhancing the dialog (at least for that listener) than the previous dialog enhancement playback parameter(s).

In some embodiments, the computing device 702 and/or cloud computing system 760, individually or in combination, may use the modified dialog enhancement playback parameter(s) rather than the corresponding prior dialog enhancement playback parameter(s) in connection with the dialog enhancement procedures described herein.

As described above, the cloud computing system 760 in some embodiments saves one or both of a “dialog enhanced” version of the audio content or a set of time-aligned dialog enhancement commands (or instructions) for a particular movie or television show so that one or both can be later transmitted to a home theater system (e.g., computing device 702 and/or playback device(s) 716) when that home theater system plays the movie or television show. In some embodiments, if usage logs of home theater systems indicate that a substantial number of listeners (e.g., more than 50%, more than 70%, more than 80%, or other portions) have increased and/or decreased the volume during some of the same portions of the audio content with and/or without dialog while the home theater system is playing the dialog enhanced audio content, then the computing system 760 may, in some embodiments, provide the modified dialog enhanced version of the audio content and/or time-aligned dialog enhancement commands to home theater systems that play that particular movie or television show in the future.

Further embodiments may additionally include the computing device 702 and/or cloud computing system 760, individually or in combination, analyzing the audio content metadata (e.g., closed caption or similar metadata comprising indications of dialog in the audio content) to identify wake words associated with one or more networked microphone devices configured to perform voice services. And if the analysis determines that the audio content comprises a wake word associated with one of the networked microphone devices, the networked microphone devices can be instructed to ignore or otherwise disregard that particular wake word instance appearing in the audio content.

For example, in embodiments where playback device 716 is or comprises a networked microphone device having a wake word of “Alexa,” and if analysis of the dialog determines that the word “Alexa” appears in the dialog of the audio content, then the playback device 716 can be instructed to ignore that instance of “Alexa” in the dialog of the audio content so that the presence of the wake word in the audio content does not trigger the playback device 716 to start listening for a voice command and potentially annoy the listener.

### VII. Example Methods

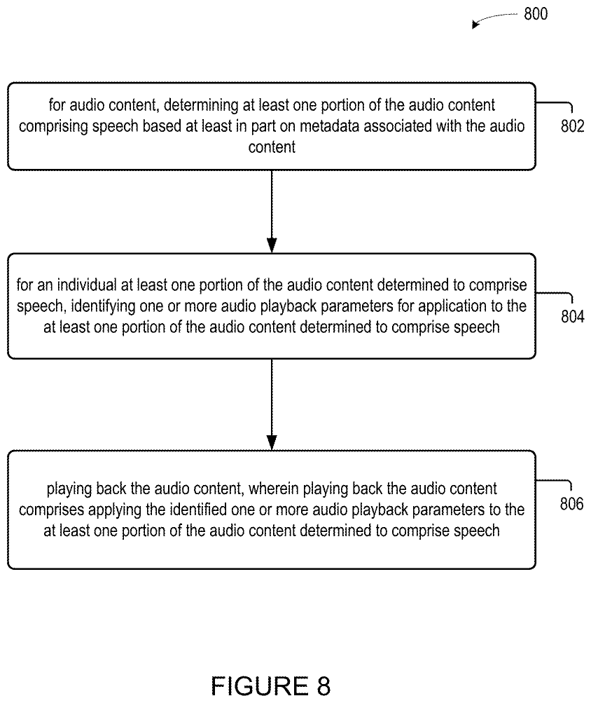

FIG. 8 shows an example method 800 performed by a computing device configured to perform speech enhancement based on metadata associated with audio content according to some embodiments.

In operation, method 800 is performed by a computing device such as computing device 702 (FIG. 7) or any other type of computing device comprising one or more processors and tangible, non-transitory computer-readable media with instructions stored therein, where the instructions, when executed, cause the computing device to perform one or more of the functions disclosed herein.

Method 800 begins at method block 802, which includes for audio content, determining at least one portion of the audio content comprising speech (or dialog) based at least in part on metadata associated with the audio content.

In some embodiments, the metadata associated with the audio content comprises closed caption data associated with the audio content. The metadata associated with the audio content may include any of type of audio content metadata disclosed herein or any other type of metadata associated with audio content that is sufficient for identifying the presence or absence of dialog in portions of audio content or any other aspect or characteristic of the audio content described herein. As described previously, in some embodiments, the audio content metadata is received via a stream or a datafile that is separate from the audio content, but in other embodiments, the audio content metadata is received via the same stream or same datafile containing the audio content.

In some embodiments, determining at least one portion of the audio content comprising speech based at least in part on metadata associated with the audio content at method block 802 includes determining at least one portion of the audio content comprising speech based on a datafile received from a cloud computing system (e.g., cloud computing system 760) or a content provider (e.g., content provider 770). In some embodiments, the datafile comprises closed caption data that is time-aligned to the audio content.

In other embodiments, determining at least one portion of the audio content comprising speech based at least in part on metadata associated with the audio content at method block 802 includes determining at least one portion of the audio content comprising speech based on a steam of audio content metadata received from a cloud computing system (e.g., cloud computing system 760) or from a content provider (e.g., content provider 770).

In still further embodiments, determining at least one portion of the audio content comprising speech based at least in part on metadata associated with the audio content at method block 802 includes determining at least one portion of the audio content comprising speech based on closed caption data received via a High-Definition Multimedia Interface (HDMI) Audio Return Channel (ARC) connection between the computing device (e.g. computing device 702) and a video display device (e.g., display device 708).

In some embodiments, determining at least one portion of the audio content comprising speech based at least in part on metadata associated with the audio content at method block 802 includes (i) determining the at least one portion of the audio content comprising speech based on a datafile comprising closed caption data that is time-aligned to the audio content, and (ii) applying a speech recognition algorithm to the at least one portion of the audio content comprising speech to identify one or more sub-portions of the audio content comprising speech, where a sub-portion of audio comprising speech has a shorter duration than a portion of audio content comprising speech. In some embodiments, determining at least one portion of the audio content comprising speech based at least in part on metadata associated with the audio content at method block 802 additionally or alternatively includes (i) applying a speech recognition algorithm to the audio content to identify at least one segment of the audio content comprising speech, and (ii) for the at least one segment of the audio content identified as comprising speech, checking whether the at least one segment includes speech based at least in part on metadata associated with the audio content.

In operation, determining at least one portion of the audio content comprising speech based at least in part on metadata associated with the audio content at method block 802 may include any other method of receiving the audio content metadata described herein from any source described herein via any communications protocol or communications link described herein with reference to system 700 in FIG. 7.

Next, method 800 advances to method block 804, which includes for an individual at least one portion of the audio content determined to comprise speech, identifying one or more audio playback parameters for application to the at least one portion of the audio content determined to comprise speech. Identifying the one or more dialog enhancement parameters may include, e.g., accessing the dialog enhancement parameters stored in local memory, looking up the dialog enhancement parameters in a local or remote database, receiving the dialog enhancement parameters via a stream of control information or via a datafile, or any other method of identification.

In some embodiments, the one or more audio playback parameters comprise equalization settings, surround sound settings, and/or volume settings configured to enhance dialog contained with audio content. In operation, a computing device implementing method 800 may apply the one or more audio playback parameters in any of the ways described earlier herein with reference to system 700 in FIG. 7.

Next, method 800 advances to method block 806, which includes playing back the audio content, wherein playing back the audio content comprises applying the identified one or more audio playback parameters to the at least one portion of the audio content determined to comprise speech.

In embodiments where the one or more audio playback parameters comprise an amplitude of one or more frequency ranges of the audio content, the function of playing back the audio content by applying the identified one or more audio playback parameters to the at least one portion of the audio content determined to comprise speech in method block 806 includes adjusting an amplitude of one or more frequency ranges of the audio content during playback of the at least one portion of the audio content determined to comprise speech. In some embodiments, applying the identified one or more audio playback parameters to the at least one portion of the audio content determined to comprise speech in method block 806 includes additionally or alternatively applying a filter to the audio content during playback, where one or more filters are configured to attenuate frequencies outside of a defined frequency range, e.g., filtering audio content outside the frequency range of spoken dialog.

In some embodiments, adjusting an amplitude of one or more frequency ranges of the audio content during playback of the at least one portion of the audio content determined to comprise speech includes one or more of (i) increasing the amplitude of the audio content within a first frequency range during playback of the at least one portion of the audio content determined to comprise speech or (ii) decreasing the amplitude of the audio content within a second frequency range different than the first frequency range during playback of the at least one portion of the audio content determined to comprise speech.

Further embodiments of method 800 may additionally include, for the audio content, (i) determining at least one portion of the audio content comprising scene-specific audio based at least in part on the metadata associated with the audio content, and (ii) for the at least one portion of the audio content determined to comprise scene-specific audio, (a) identifying at least one audio playback parameter for application to the at least one portion of the audio content comprising scene-specific audio, and (b) applying the identified at least one audio playback parameter to the at least one portion of the audio content determined to comprise scene-specific audio during playback of the audio content.

Still further embodiments of method 800 may additionally include, for the audio content, (i) determining at least one portion of the audio content lacking speech based at least in part on the metadata associated with the audio content, and (ii) for the at least one portion of the audio content determined to lack speech, (a) identifying at least one audio playback parameter for application to the at least one portion of the audio content determined to lack speech, and (b) applying the identified at least one audio playback parameter to the at least one portion of the audio content determined to lack speech during playback of the audio content.

Some embodiments of method 800 additionally include (i) after receiving a playback adjustment command (and after applying the identified one or more audio playback parameters to the at least one portion of the audio content determined to comprise speech during playback of the audio content), generating one or more modified audio playback parameters based on the playback adjustment command, and (ii) for an individual at least one portion of the audio content determined to comprise speech played after receiving the playback adjustment command, applying the one or more modified audio playback parameters to the individual at least one portion of the audio content determined to comprise speech during playback of the audio content. In operation, the playback adjustment command may include at least one of (i) a volume change, or (ii) an equalization change.

And some embodiments of method 800 may additionally include, for a specific portion of the audio content comprising speech that includes a wake word associated with a voice assistant service, informing a wake word detection algorithm to disregard the wake word within the speech contained in that specific portion of the audio content.

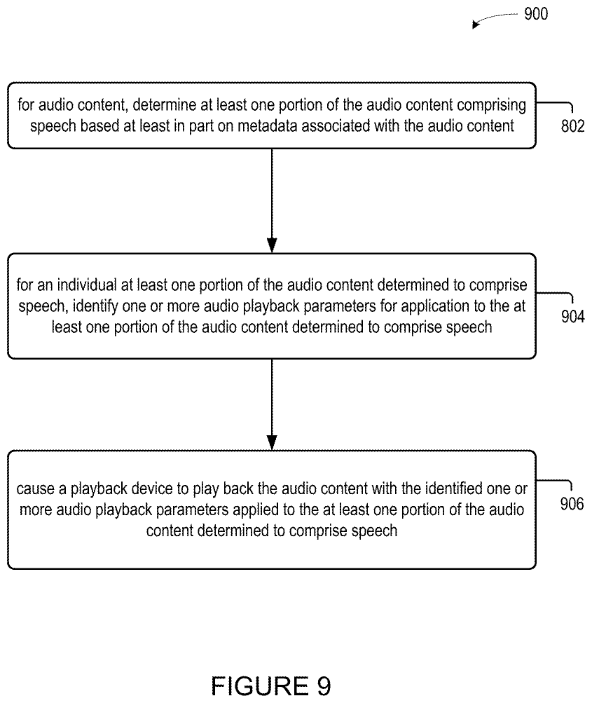

FIG. 9 shows an example method performed by a computing system configured to perform speech enhancement based on metadata associated with audio content according to some embodiments.

In operation, method 900 is performed by a computing system such as cloud computing system 760 (FIG. 7) or any other type of computing system comprising one or more processors and tangible, non-transitory computer-readable media with instructions stored therein, where the instructions, when executed, cause the computing system to perform one or more of the functions disclosed herein.

Method 900 begins at method block 902, which includes for audio content, determining at least one portion of the audio content comprising speech based at least in part on metadata associated with the audio content.

In some embodiments, the metadata associated with the audio content comprises closed caption data associated with the audio content. The metadata associated with the audio content may include any of type of audio content metadata disclosed herein or any other type of metadata associated with audio content that is sufficient for identifying the presence or absence of dialog in portions of audio content or any other aspect or characteristic of the audio content described herein. As described herein previously, in some embodiments, the audio content metadata is received via a stream or a datafile that is separate from the audio content. But in other embodiments, the audio content metadata is received via the same stream or same datafile that contains the audio content.

In some embodiments, determining at least one portion of the audio content comprising speech based at least in part on metadata associated with the audio content at method block 802 includes determining at least one portion of the audio content comprising speech based on a datafile received from a computing device (e.g., computing device 702, display device 708, playback device(s) 716, and/or controller device(s) 718) or a content provider (e.g., content provider 770). In some embodiments, the datafile comprises closed caption data that is time-aligned to the audio content.

In some embodiments, determining at least one portion of the audio content comprising speech based at least in part on metadata associated with the audio content at method block 902 includes (i) determining the at least one portion of the audio content comprising speech based on a datafile comprising closed caption data that is time-aligned to the audio content, and (ii) applying a speech recognition algorithm to the at least one portion of the audio content comprising speech to identify one or more sub-portions of the audio content comprising speech, wherein a sub-portion of audio content comprising speech has a shorter duration than a portion of the audio content comprising speech. In some embodiments, determining at least one portion of the audio content comprising speech based at least in part on metadata associated with the audio content at method block 902 additionally or alternatively includes (i) applying a speech recognition algorithm to the audio content to identify at least one portion of the audio content comprising speech, and (ii) for the at least one portion of the audio content identified as comprising speech, checking whether the at least one portion includes speech based at least in part on metadata associated with the audio content.

In operation, determining at least one portion of the audio content comprising speech based at least in part on metadata associated with the audio content at method block 902 may include any other method of receiving the audio content metadata described herein from any source described herein via any communications protocol or communications link described herein with reference to system 700 in FIG. 7.

Next, method 900 advances to method block 904, which includes for an individual at least one portion of the audio content determined to comprise speech, identifying one or more audio playback parameters for application to the at least one portion of the audio content determined to comprise speech. Identifying the one or more dialog enhancement parameters may include, e.g., accessing the dialog enhancement parameters stored in local memory, looking up the dialog enhancement parameters in a local or remote database, receiving the dialog enhancement parameters via a stream of control information or via a datafile, or any other method of identification.

In some embodiments, the one or more audio playback parameters comprise equalization settings, surround sound settings, and/or volume settings configured to enhance dialog contained with audio content. In operation, a computing device implementing method 900 may apply the one or more audio playback parameters in any of the ways described earlier herein with reference to system 700 in FIG. 7.

Next, method 900 advances to method block 906, which includes causing a playback device (or one or more playback devices) to play back the audio content with the identified one or more audio playback parameters applied to the at least one portion of the audio content determined to comprise speech.

In some embodiments, causing a playback device to play back the audio content with the identified one or more audio playback parameters applied to the at least one portion of the audio content determined to comprise speech in method block 906 includes (i) applying the one or more audio playback parameters to the at least one portion of the audio content determined to comprise speech to generate a dialog enhanced version of the audio content, and (ii) after generating the dialog enhanced version of the audio content, transmitting the dialog enhanced version of the audio content to the playback device.

In some embodiments, causing a playback device to play back the audio content with the identified one or more audio playback parameters applied to the at least one portion of the audio content determined to comprise speech in method block 906 alternatively includes (i) generating a set of audio playback control instructions that are time-aligned to the audio content, where the playback control instructions comprise instructions to apply the identified one or more audio playback parameters to the at least one portion of the audio content determined to comprise speech during playback of the audio content, and (ii) after generating the set of audio playback control instructions that are time-aligned to the audio content, transmitting, to the playback device, the set of audio playback control instructions that are time-aligned to the audio content.

In embodiments where the one or more audio playback parameters comprise an amplitude of one or more frequency ranges of the audio content, the set of audio playback control instructions that are time-aligned to the audio content comprise playback control instructions. These playback control instructions are executable by a playback device such that the playback device is configured to adjust an amplitude of one or more frequency ranges of the audio content during playback of the at least one portion of the audio content determined to comprise speech. In some embodiments, the playback control instructions for the playback device include instructions to one or both (i) increase the amplitude of the audio content within a first frequency range during playback of the at least one portion of the audio content determined to comprise speech and/or (ii) decrease the amplitude of the audio content within a second frequency range different than the first frequency range during playback of the at least one portion of the audio content determined to comprise speech.

In some embodiments where the one or more audio playback parameters include a set of one or more equalization settings, the set of audio playback control instructions that are time-aligned to the audio content include playback control instructions that cause the playback device to apply one or more filters to the at least one portion of the audio content determined to comprise speech during playback, where the one or more filters are configured to attenuate frequencies outside of a defined frequency range.

Some embodiments of method 900 additionally include, for the audio content, (i) determining at least one portion of the audio content comprising scene-specific audio based at least in part on the metadata associated with the audio content, and (ii) for the at least one portion of the audio content determined to comprise scene-specific audio, (a) identifying at least one audio playback parameter for application to the at least one portion of the audio content comprising scene-specific audio, and (ii) applying the identified at least one audio playback parameter to the at least one portion of the audio content determined to comprise scene-specific audio during playback of the audio content.

Further embodiments of method 900 additionally include, for the audio content, (i) determining at least one portion of the audio content lacking speech based at least in part on the metadata associated with the audio content, and (ii) for the at least one portion of the audio content determined to lack speech, (a) identifying at least one audio playback parameter for application to the at least one portion of the audio content determined to lack speech, and (ii) applying the identified at least one audio playback parameter to the at least one portion of the audio content determined to lack speech during playback of the audio content.

Some embodiments of method 900 additionally include (i) after receiving a playback adjustment command after applying the identified one or more audio playback parameters to the at least one portion of the audio content determined to comprise speech during playback of the audio content, generating one or more modified audio playback parameters based on the playback adjustment command, and (ii) for an individual at least one portion of the audio content determined to comprise speech played after receiving the playback adjustment command, applying the one or more modified audio playback parameters to the individual at least one portion of the audio content determined to comprise speech during playback of the audio content. In operation, the playback adjustment command may include at least one of (i) a volume change, or (ii) an equalization change.

And some embodiments of method 900 additionally include for a specific portion of the audio content comprising speech that includes a wake word associated with a voice assistant service, informing a wake word detection algorithm to disregard the wake word within the speech contained in that specific portion of the audio content.

### VIII. Conclusion

The above discussions relating to playback devices, controller devices, playback zone configurations, and media/audio content sources provide only some examples of operating environments within which functions and methods described below may be implemented. Other operating environments and configurations of media playback systems, playback devices, and network devices not explicitly described herein may also be applicable and suitable for implementation of the functions and methods.

The description above discloses, among other things, various example systems, methods, apparatus, and articles of manufacture including, among other components, firmware and/or software executed on hardware. It is understood that such examples are merely illustrative and should not be considered as limiting. For example, it is contemplated that any or all of the firmware, hardware, and/or software aspects or components can be embodied exclusively in hardware, exclusively in software, exclusively in firmware, or in any combination of hardware, software, and/or firmware. Accordingly, the examples provided are not the only ways) to implement such systems, methods, apparatus, and/or articles of manufacture.

Additionally, references herein to “embodiment” means that a particular feature, structure, or characteristic described in connection with the embodiment can be included in at least one example embodiment of an invention. The appearances of this phrase in various places in the specification are not necessarily all referring to the same embodiment, nor are separate or alternative embodiments mutually exclusive of other embodiments. As such, the embodiments described herein, explicitly and implicitly understood by one skilled in the art, can be combined with other embodiments.

The specification is presented largely in terms of illustrative environments, systems, procedures, steps, logic blocks, processing, and other symbolic representations that directly or indirectly resemble the operations of data processing devices coupled to networks. These process descriptions and representations are typically used by those skilled in the art to most effectively convey the substance of their work to others skilled in the art. Numerous specific details are set forth to provide a thorough understanding of the present disclosure. However, it is understood to those skilled in the art that certain embodiments of the present disclosure can be practiced without certain, specific details. In other instances, well known methods, procedures, components, and circuitry have not been described in detail to avoid unnecessarily obscuring aspects of the embodiments. Accordingly, the scope of the present disclosure is defined by the appended claims rather than the foregoing description of embodiments.

When any of the appended claims are read to cover a purely software and/or firmware implementation, at least one of the elements in at least one example is hereby expressly defined to include a tangible, non-transitory medium such as a memory, DVD, CD, Blu-ray, and so on, storing the software and/or firmware.

What is claimed is:

1. A playback device comprising:
at least one network interface;
one or more processors;
a tangible, non-transitory computer-readable media; and
program instructions stored in the tangible, non-transitory computer-readable media that are executable by the one or more processors such that the playback device is configured to:
for audio content, determine at least one portion of the audio content comprising speech based at least in part on metadata associated with the audio content;
for an individual at least one portion of the audio content determined to comprise speech, identify one or more audio playback parameters for application to the at least one portion of the audio content determined to comprise speech; and
play back the audio content, wherein playing back the audio content comprises applying the identified one or more audio playback parameters to the at least one portion of the audio content determined to comprise speech.

2. The playback device of claim 1, wherein the metadata associated with the audio content comprises closed caption data associated with the audio content.

3. The playback device of claim 1, wherein the one or more audio playback parameters comprise an amplitude of one or more frequency ranges of the audio content, and wherein the program instructions that are executable by the one or more processors such that the playback device is configured to play back the audio content, wherein playing back the audio content comprises applying the identified one or more audio playback parameters to the at least one portion of the audio content determined to comprise speech, comprise program instructions that are executable by the one or more processors such that the playback device is configured to:
adjust an amplitude of one or more frequency ranges of the audio content during playback of the at least one portion of the audio content determined to comprise speech.

4. The playback device of claim 1, wherein the program instructions that are executable by the one or more processors such that the playback device is configured to adjust an amplitude of one or more frequency ranges of the audio content during playback of the at least one portion of the audio content determined to comprise speech comprise program instructions that are executable by the one or more processors such that the playback device is configured to at least one of (i) increase the amplitude of the audio content within a first frequency range during playback of the at least one portion of the audio content determined to comprise speech or (ii) decrease the amplitude of the audio content within a second frequency range different than the first frequency range during playback of the at least one portion of the audio content determined to comprise speech.

5. The playback device of claim 1, wherein the program instructions that are executable by the one or more processors such that the playback device is configured to apply one or more audio playback parameters to an individual at least one portion of the audio content comprising speech during playback of the audio content comprise program instructions that are executable by the one or more processors such that the playback device is configured to:
apply a filter to the audio content during playback, wherein one or more filters are configured to attenuate frequencies outside of a defined frequency range.

6. The playback device of claim 1, wherein the program instructions that are executable by the one or more processors such that the playback device is configured to determine at least one portion of the audio content comprising speech based at least in part on metadata associated with the audio content comprise program instructions that are executable by the one or more processors such that the playback device is configured to:
determine at least one portion of the audio content comprising speech based on a datafile received via the at least one network interface, wherein the datafile comprises closed caption data that is time-aligned to the audio content.

7. The playback device of claim 1, wherein the program instructions that are executable by the one or more processors such that the playback device is configured to determine at least one portion of the audio content comprising speech based at least in part on metadata associated with the audio content comprise program instructions that are executable by the one or more processors such that the playback device is configured to:
determine at least one portion of the audio content comprising speech based on closed caption data received via a High-Definition Multimedia Interface (HDMI) Audio Return Channel (ARC) connection between the playback device and a video display device.

8. The playback device of claim 1, wherein the program instructions that are executable by the one or more processors such that the playback device is configured to determine at least one portion of the audio content comprising speech based at least in part on metadata associated with the audio content comprise program instructions that are executable by the one or more processors such that the playback device is configured to:
determine at least one portion of the audio content comprising speech based on closed caption data contained within the metadata associated with the audio content, wherein the metadata and the audio content are received via the at least one network interface.

9. The playback device of claim 1, wherein the program instructions that are executable by the one or more processors such that the playback device is configured to determine at least one portion of the audio content comprising speech based at least in part on metadata associated with the audio content comprise program instructions that are executable by the one or more processors such that the playback device is configured to:
determine the at least one portion of the audio content comprising speech based on a datafile comprising closed caption data that is time-aligned to the audio content; and
apply a speech recognition algorithm to the at least one portion of the audio content comprising speech to identify one or more sub-portions of the audio content comprising speech, wherein a sub-portion of audio comprising speech has a shorter duration than a portion of audio content comprising speech.

10. The playback device of claim 1, wherein the program instructions that are executable by the one or more processors such that the playback device is configured to determine at least one portion of the audio content comprising speech based at least in part on metadata associated with the audio content comprise program instructions that are executable by the one or more processors such that the playback device is configured to:
apply a speech recognition algorithm to the audio content to identify at least one segment of the audio content comprising speech; and
for the at least one segment of the audio content identified as comprising speech, checking whether the at least one segment includes speech based at least in part on metadata associated with the audio content.

11. The playback device of claim 1, wherein the program instructions comprise program instructions that are executable by the one or more processors such that the playback device is configured to:
for the audio content, (i) determine at least one portion of the audio content comprising scene-specific audio based at least in part on the metadata associated with the audio content, and (ii) for the at least one portion of the audio content determined to comprise scene-specific audio, (a) identify at least one audio playback parameter for application to the at least one portion of the audio content comprising scene-specific audio, and (ii) apply the identified at least one audio playback parameter to the at least one portion of the audio content determined to comprise scene-specific audio during playback of the audio content.

12. The playback device of claim 1, wherein the program instructions comprise program instructions that are executable by the one or more processors such that the playback device is configured to:
for the audio content, (i) determine at least one portion of the audio content lacking speech based at least in part on the metadata associated with the audio content, and (ii) for the at least one portion of the audio content determined to lack speech, (a) identify at least one audio playback parameter for application to the at least one portion of the audio content determined to lack speech, and (ii) apply the identified at least one audio playback parameter to the at least one portion of the audio content determined to lack speech during playback of the audio content.

13. The playback device of claim 1, wherein the program instructions comprise program instructions that are executable by the one or more processors such that the playback device is configured to:
after receiving a playback adjustment command after applying the identified one or more audio playback parameters to the at least one portion of the audio content determined to comprise speech during playback of the audio content, generate one or more modified audio playback parameters based on the playback adjustment command; and
for an individual at least one portion of the audio content determined to comprise speech played after receiving the playback adjustment command, apply the one or more modified audio playback parameters to the individual at least one portion of the audio content determined to comprise speech during playback of the audio content.

14. The playback device of claim 13, wherein the playback adjustment command comprises at least one of (i) a volume change, or (ii) an equalization change.

15. The playback device of claim 1, wherein the program instructions comprise program instructions that are executable by the one or more processors such that the playback device is configured to:
for a specific portion of the audio content comprising speech that includes a wake word associated with a voice assistant service, informing a wake word detection algorithm to disregard the wake word within the speech contained in that specific portion of the audio content.

16. A computing system comprising:
one or more network interfaces;
one or more processors;
a tangible, non-transitory computer-readable media; and
program instructions stored in the tangible, non-transitory computer-readable media that are executable by the one or more processors such that the computing system is configured to:
for audio content, determine at least one portion of the audio content comprising speech based at least in part on metadata associated with the audio content;
for an individual at least one portion of the audio content determined to comprise speech, identify one or more audio playback parameters for application to the at least one portion of the audio content determined to comprise speech; and
cause a playback device to play back the audio content with the identified one or more audio playback parameters applied to the at least one portion of the audio content determined to comprise speech.

17. The computing system of claim 16, wherein the metadata associated with the audio content comprises closed caption data associated with the audio content.

18. The computing system of claim 16, wherein the program instructions that are executable by the one or more processors such that the computing system is configured to cause a playback device to play back the audio content with the identified one or more audio playback parameters applied to the at least one portion of the audio content determined to comprise speech comprise program instructions that are executable by the one or more processors such that the computing system is configured to:
apply the one or more audio playback parameters to the at least one portion of the audio content determined to comprise speech; and
after applying the one or more audio playback parameters to the at least one portion of the audio content determined to comprise speech, transmit the audio content to the playback device.

19. The computing system of claim 16, wherein the program instructions that are executable by the one or more processors such that the computing system is configured to cause a playback device to play back the audio content with the identified one or more audio playback parameters applied to the at least one portion of the audio content determined to comprise speech comprise program instructions that are executable by the one or more processors such that the computing system is configured to:
generate a set of audio playback control instructions that are time-aligned to the audio content, wherein the playback control instructions comprise instructions to apply the identified one or more audio playback parameters to the at least one portion of the audio content determined to comprise speech during playback of the audio content; and
transmit, to the playback device, the set of audio playback control instructions that are time-aligned to the audio content.

20. The computing system of claim 19, wherein the one or more audio playback parameters comprise an amplitude of one or more frequency ranges of the audio content, and wherein the set of audio playback control instructions that are time-aligned to the audio content comprise playback control instructions that are executable by the playback device such that the playback device is configured to:
adjust an amplitude of one or more frequency ranges of the audio content during playback of the at least one portion of the audio content determined to comprise speech.

21. The computing system of claim 19, wherein the one or more audio playback parameters comprise an amplitude of one or more frequency ranges of the audio content, and wherein the set of audio playback control instructions that are time-aligned to the audio content comprise playback control instructions that are executable by the playback device such that the playback device is configured to at least one of (i) increase the amplitude of the audio content within a first frequency range during playback of the at least one portion of the audio content determined to comprise speech or (ii) decrease the amplitude of the audio content within a second frequency range different than the first frequency range during playback of the at least one portion of the audio content determined to comprise speech.

22. The computing system of claim 19, wherein the one or more audio playback parameters comprise a set of one or more equalization settings, and wherein the set of audio playback control instructions that are time-aligned to the audio content comprise playback control instructions that are executable by the playback device such that the playback device is configured to apply one or more filters to the at least one portion of the audio content determined to comprise speech during playback, wherein one or more filters are configured to attenuate frequencies outside of a defined frequency range.

23. The computing system of claim 16, wherein the program instructions that are executable by the one or more processors such that the computing system is configured to determine at least one portion of the audio content comprising speech based at least in part on metadata associated with the audio content comprise program instructions that are executable by the one or more processors such that the computing system is configured to:
determine at least one portion of the audio content comprising speech based on a datafile received via the one or more network interfaces, wherein the datafile comprises closed caption data that is time-aligned to the audio content.

24. The computing system of claim 16, wherein the program instructions that are executable by the one or more processors such that the computing system is configured to determine at least one portion of the audio content comprising speech based at least in part on metadata associated with the audio content comprise program instructions that are executable by the one or more processors such that the computing system is configured to:
determine at least one portion of the audio content comprising speech based on closed caption data contained within the metadata associated with the audio content, wherein the metadata and the audio content are received via the one or more network interfaces.

25. The computing system of claim 16, wherein the program instructions that are executable by the one or more processors such that the computing system is configured to determine at least one portion of the audio content comprising speech based at least in part on metadata associated with the audio content comprise program instructions that are executable by the one or more processors such that the computing system is configured to:
determine the at least one portion of the audio content comprising speech based on a datafile comprising closed caption data that is time-aligned to the audio content; and
apply a speech recognition algorithm to the at least one portion of the audio content comprising speech to identify one or more sub-portions of the audio content comprising speech, wherein a sub-portion of audio comprising speech has a shorter duration than a portion of audio content comprising speech.

26. The computing system of claim 16, wherein the program instructions that are executable by the one or more processors such that the computing system is configured to determine at least one portion of the audio content comprising speech based at least in part on metadata associated with the audio content comprise program instructions that are executable by the one or more processors such that the computing system is configured to:
apply a speech recognition algorithm to the audio content to identify at least one segment of the audio content comprising speech; and
for the at least one segment of the audio content identified as comprising speech, checking whether the at least one segment includes speech based at least in part on metadata associated with the audio content.

27. The computing system of claim 16, wherein the program instructions comprise program instructions that are executable by the one or more processors such that the computing system is configured to:
for the audio content, (i) determine at least one portion of the audio content comprising scene-specific audio based at least in part on the metadata associated with the audio content, and (ii) for the at least one portion of the audio content determined to comprise scene-specific audio, (a) identify at least one audio playback parameter for application to the at least one portion of the audio content comprising scene-specific audio, and (ii) apply the identified at least one audio playback parameter to the at least one portion of the audio content determined to comprise scene-specific audio during playback of the audio content.

28. The computing system of claim 16, wherein the program instructions comprise program instructions that are executable by the one or more processors such that the computing system is configured to:
for the audio content, (i) determine at least one portion of the audio content lacking speech based at least in part on the metadata associated with the audio content, and (ii) for the at least one portion of the audio content determined to lack speech, (a) identify at least one audio playback parameter for application to the at least one portion of the audio content determined to lack speech, and (ii) apply the identified at least one audio playback parameter to the at least one portion of the audio content determined to lack speech during playback of the audio content.

29. The computing system of claim 16, wherein the program instructions comprise program instructions that are executable by the one or more processors such that the computing system is configured to:
after receiving a playback adjustment command after causing a playback device to play back the audio content with the identified one or more audio playback parameters applied to the at least one portion of the audio content determined to comprise speech, generating one or more modified audio playback parameters based on the playback adjustment command; and
for an individual at least one portion of the audio content determined to comprise speech played after receiving the playback adjustment command, cause the playback device to play back the audio content with the modified one or more audio playback parameters applied to the at least one portion of the audio content determined to comprise speech after receiving the playback adjustment command.

30. The computing system of claim 29, wherein the playback adjustment command comprises at least one of (i) a volume change, or (ii) an equalization change.

31. The computing system of claim 16, wherein the program instructions comprise program instructions that are executable by the one or more processors such that the playback device is configured to:
for a specific portion of the audio content comprising speech that includes a wake word associated with a voice assistant service, informing a wake word detection algorithm to disregard the wake word within the speech contained in that specific portion of the audio content.
